(19) United States
(12) Patent Application Publication
(10) Pub. No.: US 2024/0249869 A1
(43) Pub. Date: Jul. 25, 2024

(54) INDUCTION COIL APPARATUS AND RADIO FREQUENCY MATCHING NETWORK INCORPORATING THE SAME

(71) Applicant: ASM IP HOLDING B.V., ALMERE (NL)

(72) Inventors: Ronald Anthony DECKER, Turnersville, NJ (US); Yogesh B. JAGDALE, Haddonfield, NJ (US)

(21) Appl. No.: 18/417,137

(22) Filed: Jan. 19, 2024

Related U.S. Application Data
(60) Provisional application No. 63/440,498, filed on Jan. 23, 2023.

(51) Int. Cl. H01F 27/20; H01J 37/32; H03H 7/38; H05K 7/20

(52) U.S. Cl. CPC H01F 27/20; H01J 37/32183; H03H 7/38; H05K 7/20172

(57) ABSTRACT

A radio frequency (RF) matching system may include an airflow generator configured to generate an airflow stream and an induction coil apparatus positioned within the airflow stream to be generated by the airflow generator. The induction coil apparatus may include an induction coil and an airflow guide positioned and configured to direct the airflow stream to be generated by the airflow generator over the induction coil. The airflow generator may be downstream or upstream of the induction coil apparatus in the airflow stream to be generated by the airflow generator.

### BACKGROUND

In making semiconductor devices such as microprocessors, memory chips, and another integrated circuits, the semiconductor device fabrication process uses plasma processing at different stages of fabrication. Plasma processing involves energizing a gas mixture by imparting energy to the gas molecules by the introduction of RF (radio frequency) energy into the gas mixture. This gas mixture is typically contained in a vacuum chamber, also called a plasma chamber, and the RF energy is introduced through electrodes or other means in the chamber. In a typical plasma process, the RF generator generates power at the desired RF frequency and power, and this power is transmitted through the RF cables and networks to the plasma chamber.

To provide efficient transfer of power from the RF generator to the plasma chamber, an RF matching network is positioned between the RF generator and the plasma chamber. The purpose of the RF matching network is to transform the plasma impedance to a value suitable for the RF generator. In many cases, particularly in the semiconductor fabrication processes, the RF power is transmitted through 50 Ohm coaxial cables and the system impedance (output impedance) of the RF generators is also 50 Ohm. On the other hand, the impedance of the plasma, driven by the RF power, varies. The impedance on the input side of the RF matching network must be transformed to non-reactive 50 Ohm (i.e., 50+j0) for maximum power transmission. RF matching network perform this task of continuously transforming the plasma impedance to 50 Ohm for the RF generator.

A typical RF matching network may include one or more inductors or electrical coils. Large RF inductors or electrical coils in high power matching networks can get over 100° C. in temperature due to conduction losses in the metal surface, even with significant airflow for cooling the induction coils. This is because large open space is present in the center of these large coils, and most of the cooling air flows through the path of least resistance, i.e., the center of the coil. The heat that is generated in the coil remains around the metal surface of the induction coil.

Existing solutions may include using higher power fans and/or larger inductors with greater surface areas. In some instances, the inductors are simply left to operate at higher temperatures. However, larger inductors require larger enclosures. Allowing the inductors to operate at high temperatures may result in oxidation, cause mounting hardware to become loose, and/or melt insulators. Thus, a need exists to improve upon existing cooling techniques for induction coils operating in RF matching networks and/or systems.

### SUMMARY

In some embodiments, a radio frequency (RF) matching system may include an airflow generator configured to generate an airflow stream and an induction coil apparatus positioned within the airflow stream to be generated by the airflow generator. The induction coil apparatus may include an induction coil and an airflow guide positioned and configured to direct the airflow stream to be generated by the airflow generator over the induction coil.

In some embodiments, an induction coil apparatus for use in a radio frequency matching network may include an induction coil and an airflow guide configured to direct an incoming airflow stream over the induction coil.

In some embodiments, an airflow diverter for cooling an induction coil in a radio frequency matching network may include a diverter body and a plurality of spacer ribs. The diverter body may be configured to be positioned in a central coil cavity defined by an induction coil. The plurality of spacer ribs may protrude from an outer surface of the diverter body. The plurality of spacer ribs may be configured to mount the diverter body to the induction coil and configured to maintain an annular gap between the diverter body and the induction coil.

In some embodiments, a method of cooling an induction coil in a radio frequency matching network may include generating an airstream flow and directing at least a portion of the airstream flow over the induction coil using an airflow guide.

In some embodiments, a method of cooling an induction coil in a radio frequency matching network may include generating an airstream flow toward an induction coil apparatus comprising the induction coil, the induction coil defining a central coil cavity that extends along a central axis. The method may further include diverting a portion of the airstream flow radially outward from the central axis so that the portion of the airstream flow flows through an outer region of the central coil cavity and over the induction coil rather than through a central region of the central coil cavity. In some embodiments, a method of mounting an airflow diverter comprising a diverter body to an induction coil in a radio frequency matching network may include positioning at least a portion of a main portion of the diverter body of the airflow diverter into a central coil cavity of the induction coil, the central coil cavity extending along a central axis of the induction coil. The method may further include positioning at least a portion of a tapered portion of the diverter body of the airflow diverter outside the central coil cavity of the induction coil.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The features of the exemplary embodiments of the present invention will be described with reference to the following drawings, where like elements are labeled similarly, and in which:

FIG. 1 is a block diagram of a semiconductor processing system according to some embodiments.

FIGS. 2A and 2B are simplified schematics of exemplary matching networks according to some embodiments.

FIG. 3 is a simplified schematic of an exemplary RF matching system according to some embodiments.

FIG. 4 shows an isometric view of an induction coil apparatus according to some embodiments.

FIG. 5 illustrates the induction coil apparatus of FIG. 4 with mounting brackets according to some embodiments.

FIG. 6 shows an isometric view of an induction coil of the induction coil apparatus of FIG. 4 according to some embodiments.

FIG. 7 shows an isometric view of an airflow diverter of the induction coil apparatus of FIG. 4 according to some embodiments.

FIG. 8 shows a cross-sectional view of the induction coil apparatus of FIG. 4, viewed along line VIII-VIII in FIG. 4.

FIG. 9 shows a cross-sectional view of the induction coil apparatus of FIG. 4, viewed along line IX-IX in FIG. 4.

FIG. 10 shows a front exploded view of the airflow diverter of FIG. 7.

FIG. 11 shows a rear exploded view of the airflow diverter of FIG. 7, rotated by 90° from FIG. 10.

FIG. 12 shows a top plan view of a diverter body of the airflow diverter of FIG. 7.

FIG. 13 shows a right elevation view of the diverter body of the airflow diverter of FIG. 7.

FIG. 14 shows a rear elevation view of the diverter body of the airflow diverter of FIG. 7.

FIG. 15 shows a front elevation view of a spacer of the airflow diverter of FIG. 7.

FIG. 16 shows a top plan view of the spacer of the airflow diverter of FIG. 7.

FIG. 17 shows a right elevation view of the spacer of the airflow diverter of FIG. 7.

FIGS. 18A, 18B, 18C, and 18D schematically illustrate turbulator features according to some embodiments.

FIG. 19 schematically illustrates exemplary air baffles positioned around an induction coil apparatus according to some embodiments.

FIG. 20 shows a cross-sectional view of the air baffle and induction coil apparatus of FIG. 19, viewed along line XX-XX in FIG. 19.

FIG. 21 schematically illustrates additional exemplary air baffles positioned around an induction coil apparatus according to some embodiments.

FIG. 22 schematically illustrates additional exemplary air baffles positioned around an induction coil apparatus according to some embodiments.

FIGS. 23A and 23B schematically illustrate additional exemplary air baffles positioned around an induction coil apparatus according to some embodiments.

FIGS. 24A, 24B, 24C, and 24D schematically illustrate various diverter bodies according to some embodiments.

FIG. 25 is a flow chart showing a method of cooling an induction coil in a radio frequency matching network according to some embodiments.

FIG. 26 is a flow chart showing a method of cooling an induction coil in a radio frequency matching network according to some embodiments.

FIG. 27 is a flow chart showing a method of mounting an airflow diverter to an induction coil in a radio frequency matching network according to some embodiments.

All drawings are schematic and not necessarily to scale. However, relative positioning and sizing of components and elements within a drawing are considered accurate. Parts given a reference numerical designation in one figure may be considered to be the same parts where they appear in other figures without a numerical designation for brevity unless specifically labeled with a different part number and described herein.

### DETAILED DESCRIPTION

The features and benefits of the invention are illustrated and described herein by reference to exemplary (“example”) embodiments. This description of exemplary embodiments is intended to be read in connection with the accompanying drawings, which are to be considered part of the entire written description. Accordingly, the disclosure expressly should not be limited to such exemplary embodiments illustrating some possible non-limiting combination of features that may exist alone or in other combinations of features.

In the description of embodiments disclosed herein, any reference to direction or orientation is merely intended for convenience of description and is not intended in any way to limit the scope of the present invention. Relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation. Terms such as “attached,” “affixed,” “connected,” “coupled,” “interconnected,” and similar refer to a relationship wherein structures are secured or attached to one another either directly or indirectly through intervening structures, as well as both movable or rigid attachments or relationships, unless expressly described otherwise.

As used throughout, any ranges disclosed herein are used as shorthand for describing each and every value that is within the range. Any value within the range can be selected as the terminus of the range.

### Semiconductor Processing System

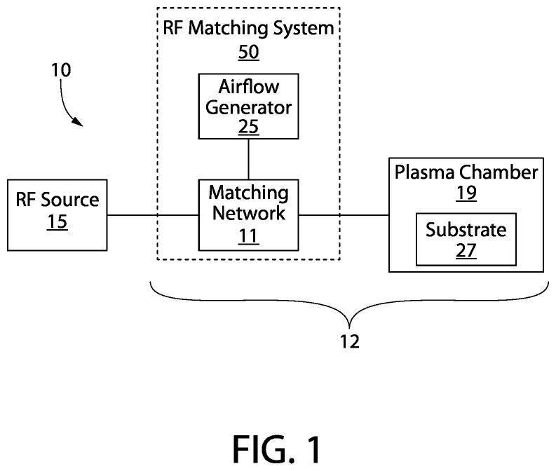

Referring to FIG. 1, a semiconductor device processing system 10 utilizing an RF generator 15 is shown. The system 10 includes an RF generator 15 and a semiconductor processing tool 12. In some embodiments, the semiconductor processing tool 12 may include a RF matching system 50 and a plasma chamber 19. The RF matching system 50 may include a matching network 11 and an airflow generator 25. The airflow generator 25 may be configured to generate an airflow stream for cooling one or more components of the matching network 11 as will be discussed in more detail below. Although the airflow generator 25 and the matching network 11 are shown as separate units in FIG. 1, the airflow generator 25 and the matching network 11 may be one integrated unit in some embodiments. In some embodiments, the generator 15 or other power source may form part of the semiconductor processing tool.

The semiconductor device can be a microprocessor, a memory chip, or other type of integrated circuit or device. A substrate 27 can be placed in the plasma chamber 19, where the plasma chamber 19 is configured to deposit a material layer onto the substrate 27 or etch a material layer from the substrate 27. Plasma processing involves energizing a gas mixture by imparting energy to the gas molecules by introducing RF energy into the gas mixture. This gas mixture is typically contained in a vacuum chamber (the plasma chamber 19), and the RF energy is typically introduced into the plasma chamber 19 through electrodes. Thus, the plasma can be energized by coupling RF power from an RF source 15 into the plasma chamber 19 to perform deposition or etching.

In a typical plasma process, the RF generator 15 generates power at a radio frequency—which is typically within the range of 3 kHz and 300 GHz—and this power is transmitted through RF cables and networks to the plasma chamber 19. In order to provide efficient transfer of power from the RF generator 15 to the plasma chamber 19, an intermediary circuit is used to match the fixed impedance of the RF generator 15 with the variable impedance of the plasma chamber 19. Such an intermediary circuit is commonly referred to as an RF impedance matching network, or more simply as an RF matching network. The purpose of the RF matching network 11 is to transform the variable plasma impedance to a value that more closely matches the fixed impedance of the RF generator 15. Commonly owned U.S. patent application Ser. No. 14/669,568, the disclosure of which is incorporated herein by reference in its entirety, provides an example of such a matching network.

### Exemplary RF Matching Networks

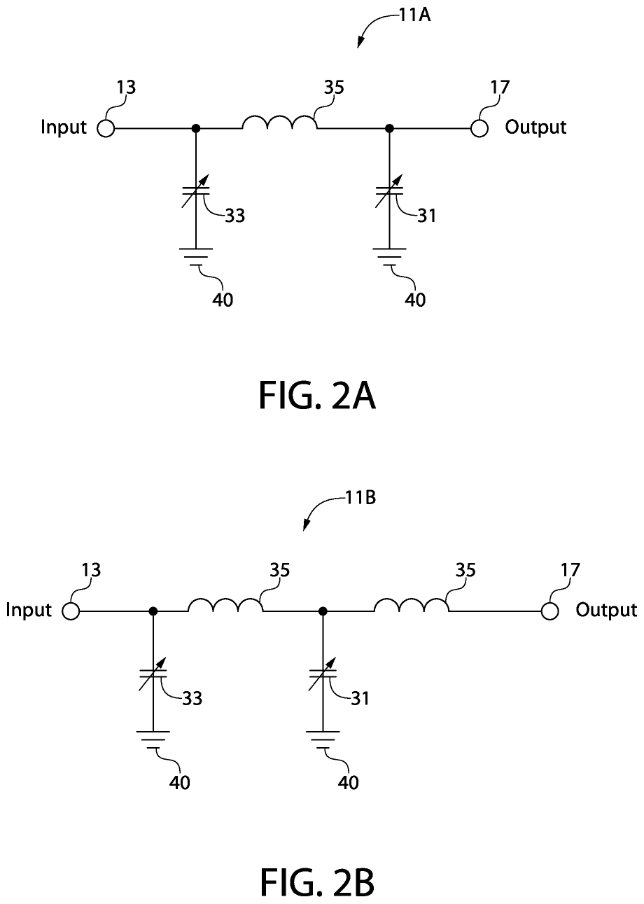

FIGS. 2A and 2B are simplified schematics of exemplary matching networks, specifically Π (pi) matching networks 11A, 11B, each of which may be implemented in a semiconductor processing system 10. Each of the matching networks 11A, 11B may include an RF input 13 connected to an RF source 15 and an RF output 17 connected to a plasma chamber 19. Each of the matching networks 11A, 11B may also include a variable capacitor 31 and a shunt variable capacitor 33 coupled to ground 40. Each of the matching networks 11A, 11B may further include one or more inductors 35. Note that these are only exemplary RF matching networks and any variety of matching networks (e.g., II, L, and/or T) can be implemented. The inductors 35 and/or capacitors 31, 33 may be utilized in any manner and/or positioned at any suitable locations in a matching network, depending on the implementation. Commonly owned U.S. patent application Ser. No. 16/879,928, the disclosure of which is incorporated herein by reference in its entirety, provides additional examples of matching networks.

Depending on the application, large electrical coils may be used for the inductors 35. In some embodiments, the diameter of the wire forming the inductors 35 may range from about 0.0641″ to about 0.75″—including all values and sub-ranges thereof, and the coil diameter may range from about 0.5″ to about 6″—including all values and sub-ranges thereof. However, due to the skin effect at RF, electric current may flow mainly near the surface of the coil, resulting in significant heating of the inductors 35. In some instances, the operating temperature of large inductors 35 in high power matching networks may get over 100° C. due to conduction losses in the metal surface. An airflow stream may be directed to the induction coils for cooling the inductors 35. However, even with significant airflow for cooling the coil, effective cooling may not be achieved conventionally because most of the air may flow right through the large opening in the center of the coil without removing the heat generated at the surface of the coil.

RF Matching System with Improved Cooling

To improve the cooling of the induction coil and to reduce the operating temperature of the inductor 35, the present disclosure provides an airflow diverter that may be positioned within a central coil cavity of the induction coil. As will be discussed in more detail below, the airflow diverter may be configured to divert the airflow stream from a central region of the induction coil radially outward into an outer region of the induction coil and over the induction coil, thereby achieving effective cooling of the inductor 35.

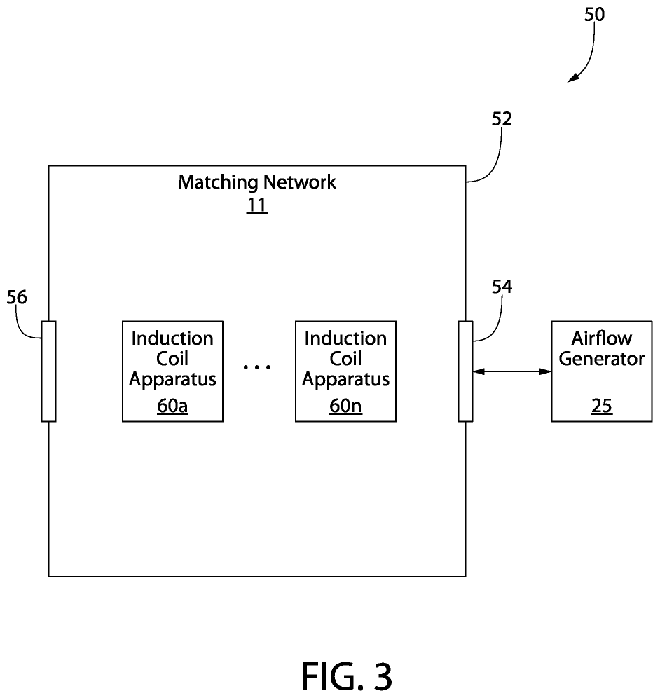

Referring to FIG. 3, an RF matching system 50 with improved cooling of the inductors 35 according to some embodiments is shown. The RF matching system 50 may include a matching network 11 and an airflow generator 25. The matching network 11 may include one or more induction coil apparatus 60a, . . . , induction coil apparatus 60n, and other electrical components (not shown FIG. 3) arranged in any suitable manner depending on the application. Each of the induction coil apparatuses 60 may include an inductor, such as inductor 35 as described above with reference to FIGS. 2A and 2B, and an airflow guide. The one or more induction coil apparatus 60 and the airflow generator 25 may be configured such that the induction coil apparatus 60 may be positioned within the airflow stream generated by the airflow generator 25. The airflow guide may be positioned and/or configured to direct the airflow stream generated by the airflow generator 25 over the induction coil so as to improve the cooling of the induction coil, as will be discussed in more detail below.

In some embodiments, the various components of the matching network 11, including the induction coil apparatuses 60, may be disposed within an enclosure or housing 52. The airflow generator 25 may be disposed outside the housing 52 to minimize or eliminate any interference with the operation of the matching network 11. The housing 52 may include a first vent 54 and a second vent 56. One of the first and/or second vents 54, 56 may function as an air inlet vent, and the other one of the first and/or second vents 54, 56 may function as an air outlet vent.

The airflow generator 25 may be in fluid communication with the inside of the housing 52 via one of the first and/or second vents 54, 56, for example, the first vent 54 as shown in FIG. 3. In some embodiments, such fluid communication may be established by placing the airflow generator 25 adjacent to the first vent 54. In some embodiments, the fluid communication may be established by connecting the airflow generator 25 and the first vent 54 using a conduit.

In some embodiments, the airflow generator 25 may be configured to generate an airflow stream that may enter the housing 52 via the first vent 54 to flow over the one or more induction coil apparatuses 60 and then exit the housing 52 via the second vent 56. In these instances, the airflow generator 25 may be upstream of the induction coil apparatus 60 in the airflow stream, and the airflow generator 25 may be configured to push or blow air into the housing 52 via the first vent 54, and the first vent 54 functions as the inlet vent and the second vent 56 as the outlet vent. In some embodiments, the airflow generator 25 may be configured to generate an airflow stream that may enter the housing 52 via the second vent 56 to flow over the one or more induction coil apparatuses 60 and then exit the housing 52 via the first vent 54. In these instances, the airflow generator may be downstream of the induction coil apparatus 60 in the airflow stream, and the airflow generator 25 may be configured to pull or suck air out of the housing 52 via the first vent 54, and the second vent 56 functions as the inlet vent and the first vent 54 as the outlet vent.

Note that the arrangement of the one or more induction coil apparatuses 60, the first and/or second vents 54, 56, and/or the airflow generator 25 in FIG. 3 is only exemplary. The various components may be arranged in any desirable configuration. The first and/or second vents 54, 56 may be positioned on opposing walls of the housing 52, such as shown in FIG. 3, or may be positioned on adjacent walls or the same wall of the housing 52. The one or more induction coil apparatuses 60 may be aligned or may be oriented at an angle with each other, depending on the design requirements of the matching network 11. Further, in some embodiments, the airflow generator 25 may be positioned inside the housing 52, and the airflow generator 25 may form an integrated part of the matching network 11. Although only one airflow generator 25 is shown in FIG. 3, more than one airflow generators 25 may be utilized. For example, in some embodiments, an airflow generator 25 may be positioned adjacent to each of the first vent 54 and/or the second vent 56. Each of the airflow generators 25 may be configured to push/blow or to pull/such air, depending on the particular arrangement. The one or more airflow generators 25 may be positioned inside or outside the housing 52.

### Induction Coil Apparatus

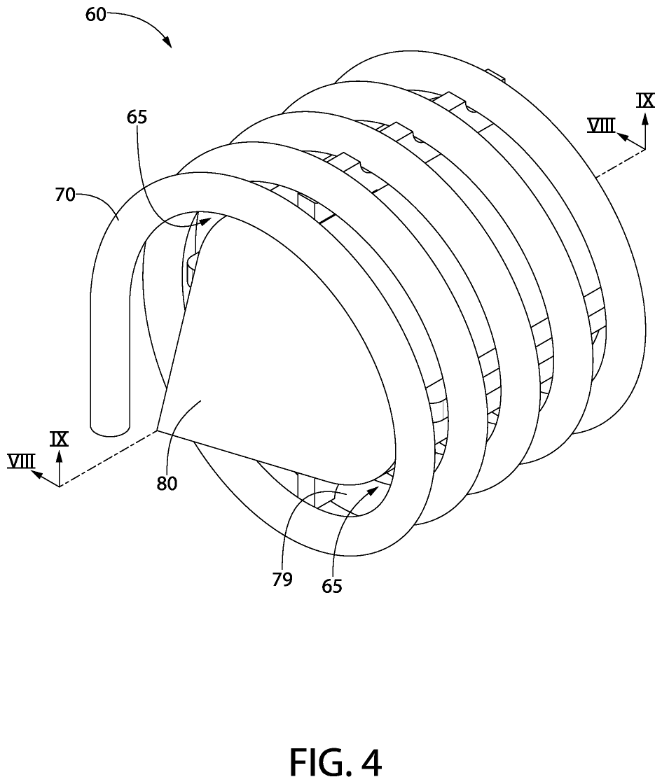

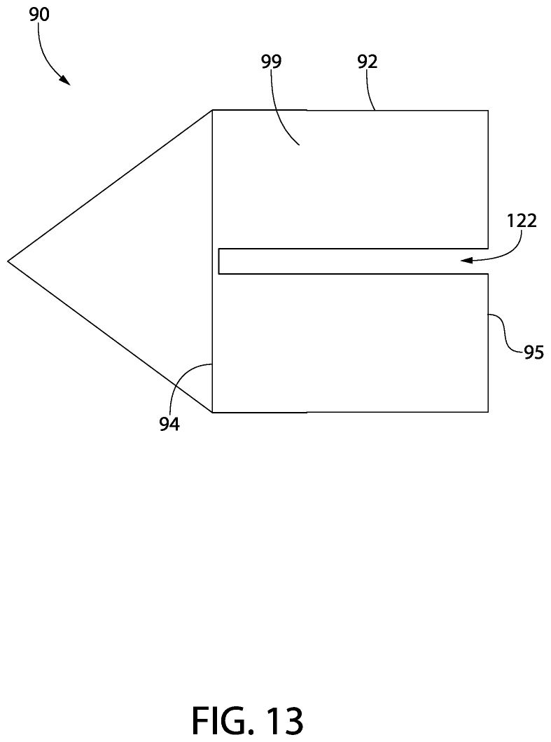

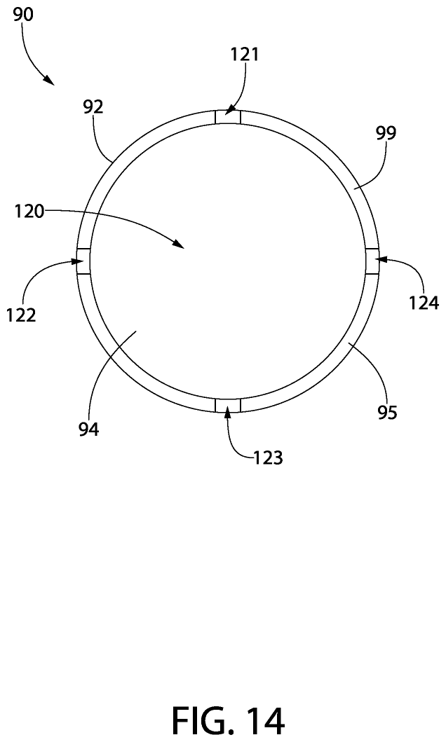

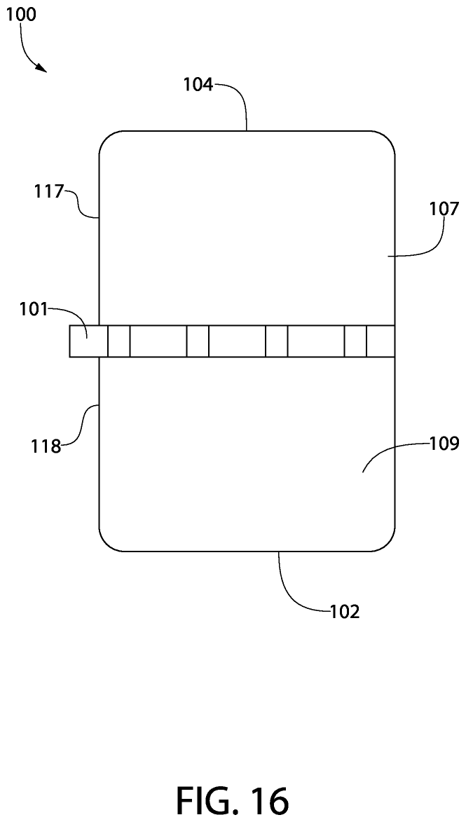

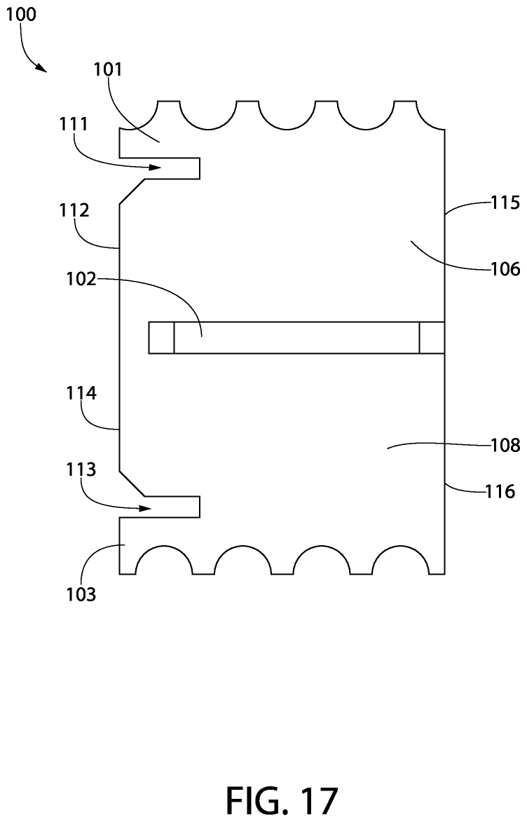

With reference to FIGS. 4 to 24, various embodiments of the induction coil apparatus 60 and the airflow guide will be described. In some embodiments, the airflow guide may include an airflow diverter. In some embodiments, the airflow guide may include one or more air baffles. In some embodiments, the airflow guide may include a combination of an airflow diverter and/or one or more air baffles. In some embodiments, the airflow guide is configured to be mounted to the induction coil. In some embodiments, the airflow guide including the airflow diverter and/or the one or more air baffles may be positioned and/or configured to direct the airflow stream radially through a helical space that exists between adjacent coil turns of the induction coil so as to achieve effectively cooling of the induction coil.

Referring to FIG. 4, an induction coil apparatus 60 according to some embodiments is shown. The induction coil apparatus 60 may include an induction coil 70 and an airflow guide, which may include an airflow diverter 80. The airflow diverter 80 may be disposed in a central cavity of the induction coil 70. The airflow diverter 80 may be mounted to and supported by the induction coil 70 with minimal contact such that an annular gap 65 may exist between an inner surface 79 of the induction coil 70 and the airflow diverter 80.

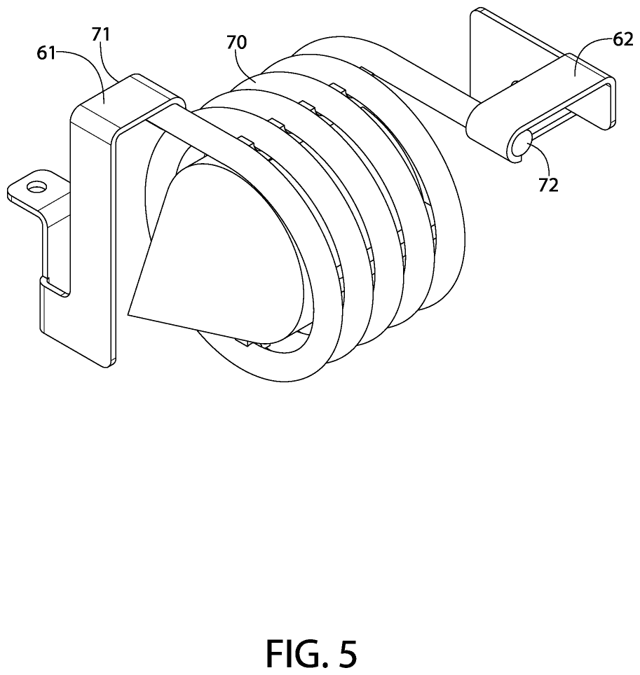

Referring to FIG. 5, mounting brackets 61, 62 may be used to couple the induction coil 70 to the other components of the matching network 11. Each of the mounting brackets 61, 62 may be coupled to a terminal end or portion 71, 72 of the induction coil 70. The mounting brackets 61, 62 may be configured such that the induction coil 70 may be supported in a floating arrangement.

### Induction Coil

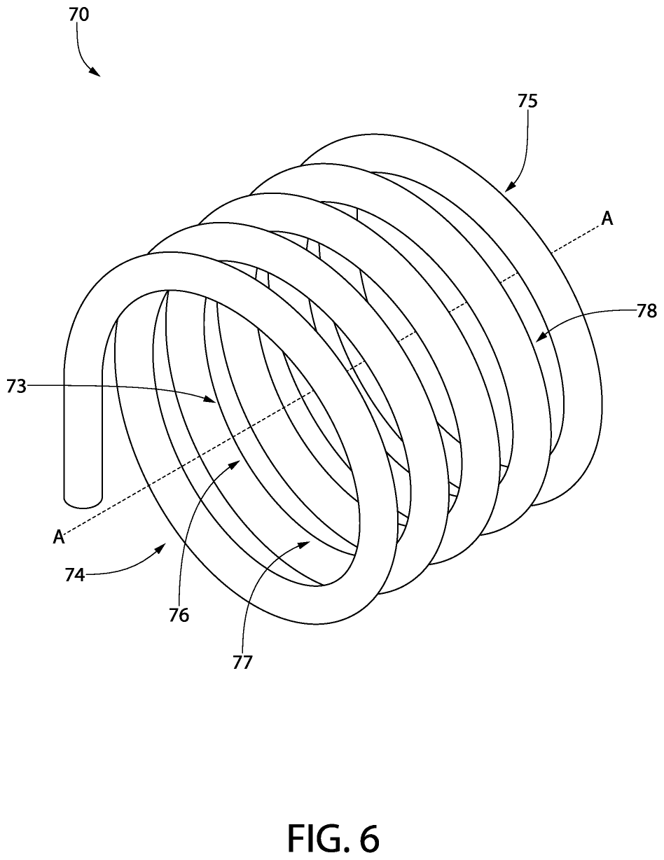

Referring to FIG. 6, the induction coil 70 without the airflow diverter 80 disposed therein is shown. The induction coil 70 may define a central coil cavity 73. The central coil cavity 73 may extend along a central axis A-A of the induction coil 70 from a first open end 74 to a second open end 75. The central coil cavity 73 includes a central region 76 located along the central axis A-A and an outer region 77 adjacent the induction coil 70 and circumferentially surrounding the central region 76. The airflow diverter 80 may be positioned within the central region 76 of the central coil cavity 73. A helical space 78 may exist between adjacent coil turns of the induction coil 70. The helical space 78 may be in spatial communication with the outer region 77 of the central coil cavity 73.

### Airflow Diverter

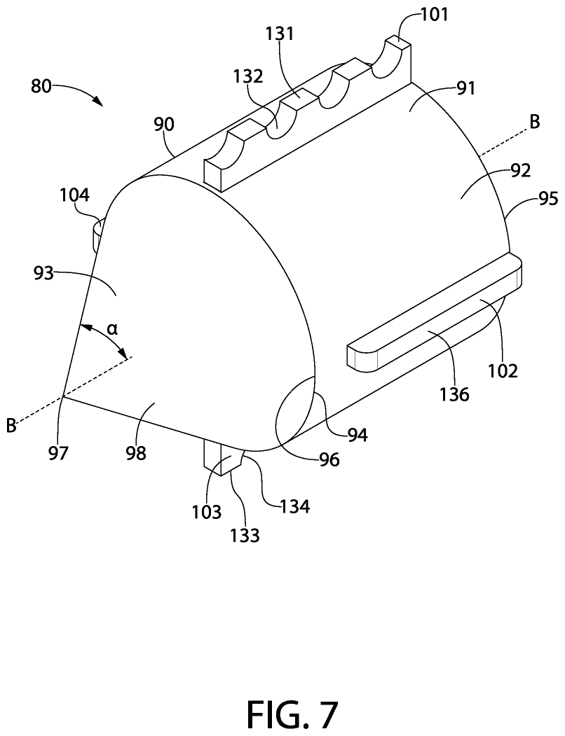

Referring to FIG. 7, an isometric view of the airflow diverter 80 is shown. The airflow diverter 80 may include a diverter body 90 extending along a central axis B-B of the diverter body 90 and spacer ribs 101, 102, 103, 104 protruding from an outer surface 91 of the diverter body 90. The spacer ribs 101, 102, 103, 104 may be configured to mount the airflow diverter 80 to the induction coil 70 such that the central axis B-B of the diverter body 90 and the central axis A-A of the induction coil 70 may be substantially aligned and the annular gap 65 between the outer surface 91 of the diverter body 90 and the inner surface 79 of the induction coil 70 may be maintained.

### Diverter Body

The diverter body 90 may include a main portion 92 and a tapered portion 93 extending from the main portion 92. Referring back to FIGS. 4 and 6, in some embodiments, the main portion 92 (or at least a portion thereof) of the diverter body 90 may be located between the first open end 74 and the second open end 75 of the central coil cavity 73, and the tapered portion 93 (or at least a portion thereof) of the diverter body 90 may protrude outward from the first open end 74 of the central coil cavity 73.

In some embodiments, the main portion 92 may have a transverse cross-sectional profile that may be substantially constant along the central axis B-B of the diverter body 90. The transverse cross-sectional profile of the main portion 92 may be generally symmetric about the central axis B-B of the diverter body 90. In some embodiments, the main portion 92 may include a cylindrical body or a tubular body. The transverse cross-sectional profile of the main portion 92 may be circular. In some embodiments, the main portion 92 may have a prism or column shape having a non-circular transverse cross-sectional profile, e.g., a polygonal or any suitably shaped profile. In some embodiments, the main portion 92 may have a transverse cross-sectional profile that may not be constant along the central axis B-B of the diverter body 90. For example, the main portion 92 may be tapered and form a frustum shape. In some embodiments, the main portion 92 may include a transverse cross-sectional profile that gradually increase in size from a proximal end 94 to a distal end 95 of the main portion 92. The main portion 92 may include a solid or hollow center.

The tapered portion 93 may extend from a proximal end 96 of the tapered portion 93 and terminate at a distal end 97 of the tapered portion 93. The proximal end 96 of the tapered portion 93 may also be the proximal end 94 of the main portion 92. The tapered portion 93 may include a cross-sectional profile that may decrease in size moving from the proximal end 96 toward the distal end 97 of the tapered portion 93 to minimize pressure drop of the airflow stream as the airflow stream approaches the induction coil 70. The cross-sectional profile of the tapered portion 93 may be symmetric about the central axis B-B of the diverter body 90. In some embodiments, the transition between the tapered portion 93 and the main portion 92 may be gradual or smooth, such as a curved transition. In some embodiments, the transition between the tapered portion 93 and the main portion 92 may form an edge, such as shown in FIG. 7.

In some embodiments, the tapered portion 93 may be in the form of a cone. In some embodiments, the tapered portion 93 may be in the form of a cone that terminates in an apex point, such as shown in FIG. 7. The distal end 97 of the tapered portion 93 may form a distal tip of the tapered portion 93. In some embodiments, the tapered portion 93 may have a side surface 98 that may extend from the proximal end 96 of the tapered portion 93 to the distal end 97 of the tapered portion 93 in a straight or linear fashion. An angle α between the side surface 98 and the central axis B-B of the diverter body 90 may range from about 25° to about 60°—including all values and sub-ranges thereof. For example, in some embodiments, the angle α between the side surface 98 and the central axis B-B of the diverter body 90 may range from about 25° to about 30°, from about 25° to about 35°, from about 25° to about 40°, from about 25° to about 45°, from about 25° to about 50°, from about 25° to about 55°, from about 25° to about 60°, from about 30° to about 35°, from about 30° to about 40°, from about 30° to about 45°, from about 30° to about 50°, from about 30° to about 55°, from about 30° to about 60°, from about 35° to about 40°, from about 35° to about 45°, from about 35° to about 50°, from about 35° to about 55°, from about 35° to about 60°, from about 40° to about 45°, from about 40° to about 50°, from about 40° to about 55°, from about 40° to about 60°, from about 45° to about 50°, from about 45° to about 55°, from about 45° to about 60°, from about 50° to about 55°, from about 50° to about 60°, from about 55° to about 60°, or any another suitable values or ranges.

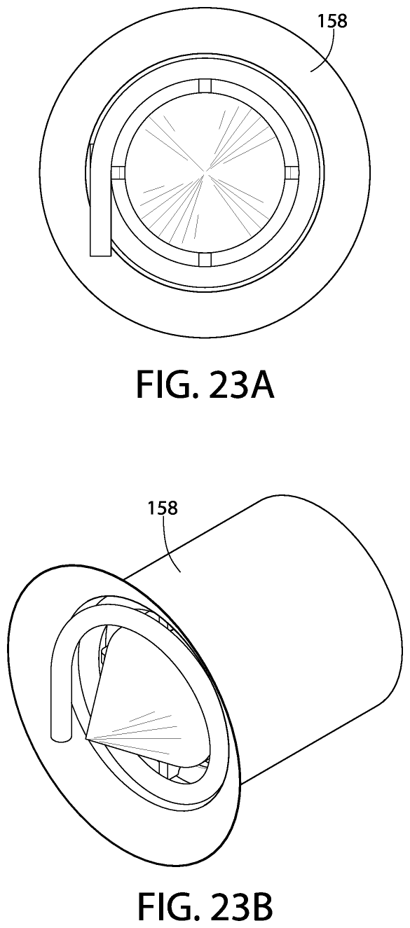

In some embodiments, the tapered portion 93 may be in the form of a dome which may include a surface area that may be rounded at the distal end 97 of the tapered portion 93, such as shown in FIG. 24A. The side surface 98 may extend from the proximal end 96 of the tapered portion 93 to the distal end 97 of the tapered portion 93 in a curved manner. In some embodiments, the tapered portion 93 may be in the form of a truncated cone, such as shown in FIG. 24C, or truncated dome, such as shown in FIG. 24B, and may have a surface area that may be substantially flat at the distal end 97 of the tapered portion 93.

Although cones or domes are described as exemplary forms of the tapered portion 93, the tapered portion 93 may be of any suitable three-dimensional form. In some embodiments, the side surface 98 of the tapered portion 93 may be smooth or extend continuously from the proximal end 96 of the tapered portion 93 to the distal end 97 of the tapered portion 93. In some embodiments, the side surface 98 of the tapered portion 93 may defined a stepped profile between the proximal end 96 of the tapered portion 93 and the distal end 97 of the tapered portion 93, such as shown in FIG. 24D. The tapered portion 93 may be in the form of the stepped cone, stepped dome, stepped frustum, etc. The tapered portion 93 may include a solid or hollow center.

### Spacer Ribs

With continued reference to FIG. 7, each of the spacer ribs 101, 102, 103, 104 may extend along a rib axis that may be substantially parallel to the central axis B-B of the diverter body 90. In some embodiments, the spacer ribs 101, 102, 103, 104 may have a common rib length. In some embodiments, the spacer ribs 101, 102, 103, 104 may have different rib lengths. The rib length of each spacer rib 101, 102, 103, 104 may be defined by a distance between a leading end of the spacer rib 101, 102, 103, 104 proximate the proximal end 94 of the main portion 92 and a trailing end of the spacer rib 101, 102, 103, 104 proximate the distal end 95 of the main portion 92.

In some embodiments, the spacer ribs 101, 102, 103, 104 may extend along a major portion of a length of the main portion 92 of the diverter body 90. The length of the main portion 92 of the diverter body 90 may be defined as a distance between the proximal end 94 and the distal end 95 of the main portion 92. In some embodiments, the spacer ribs 101, 102, 103, 104 may extend along substantially the entire length of the main portion 92 of the diverter body 90.

One or more of the spacer ribs 101, 102, 103, 104 may be configured to axially retain the airflow diverter 80 within the induction coil 70. In some embodiments, the one or more spacer ribs 101, 102, 103, 104 may be configured to axially retain the airflow diverter 80 within the induction coil 70 through mechanical interference with the induction coil 70.

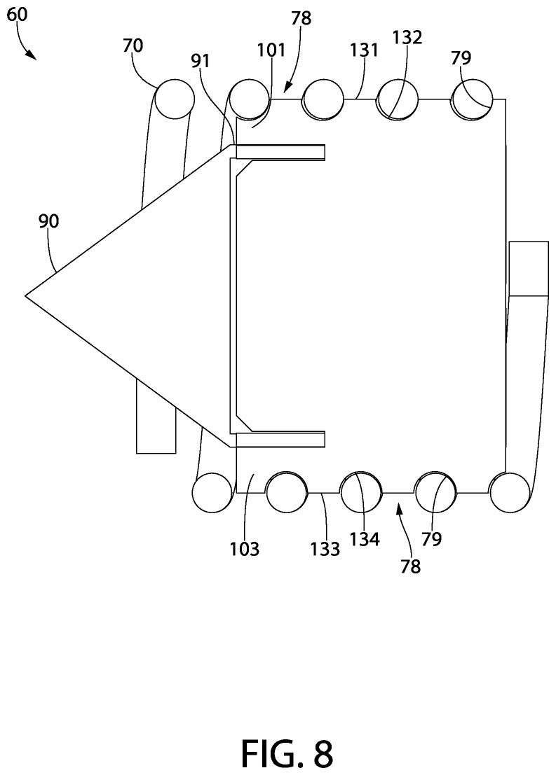

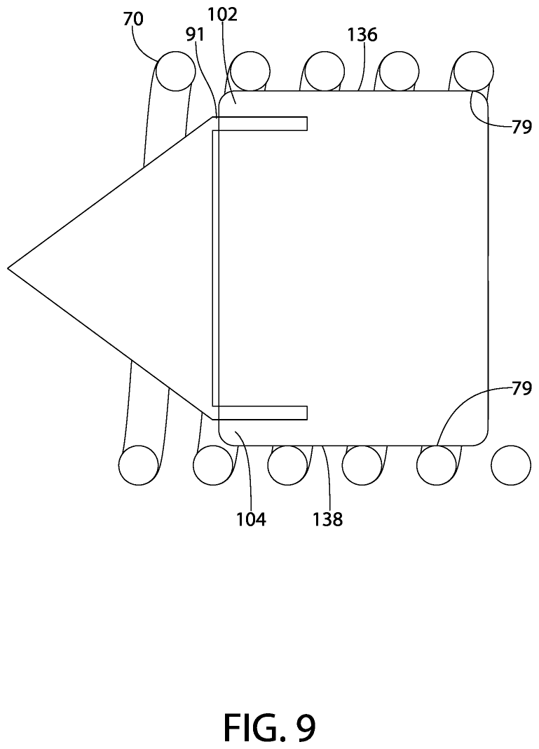

FIG. 8 schematically illustrates a cross-sectional view of the induction coil apparatus 60, viewed along line VIII-VIII in FIG. 4. FIG. 9 schematically illustrates a cross-sectional view of the induction coil apparatus 60, viewed along line IX-IX in FIG. 4.

Referring to FIGS. 7 and 8, in some embodiments, spacer rib 101 and spacer rib 103 may be configured to axially retain the airflow diverter 80 within the induction coil 70. Specifically, in some embodiments, each of spacer rib 101 and spacer rib 103 may include one or more protuberances 131, 133 that extend into the helical space 78 between adjacent coil turns of the induction coil 70. Grooves 132, 134 may be formed between adjacent ones of the protuberances 131, 133, and the induction coil 70 may nest within the grooves 132, 134.

The placement of the protuberances 131, 133 along the spacer ribs 101, 103 may be configured to substantially match the helical space 78 between the adjacent coil turns of the induction coil 70, and the placement grooves 132, 134 may be configured to substantially match the coil turns of the induction coil 70. As such, the airflow diverter 80 may be moved axially along the central axis A-A of the induction coil 70 within the central coil cavity 73 of the induction coil 70 by rotating the airflow diverter 80 relative to the induction coil 70. Without such rotation, axial movement of the airflow diverter 80 relative to the induction coil 70 may be limited.

It is noted that although in the embodiment shown, spacer ribs 102, 104 may each include a substantially flat radially outward facing surface 136, 138, in some embodiments, grooves and protuberances may also be formed along spacer ribs 102, 104, similar to the grooves 132, 134 and the protuberances 131, 133 formed along spacer ribs 101, 103.

With further reference to FIGS. 4, 8, and 9, the spacer ribs 101, 102, 103, 104 may contact the inner surface 79 of the induction coil 70 such than the airflow diverter 80 may be mounted to and supported by the induction coil 70 and the annular gap 65 between the induction coil 70 and the airflow diverter 80 may be maintained. Specifically, the grooves 132, 134 of spacer ribs 101, 103 and the radially outward facing surfaces 136, 138 of spacer ribs 102, 104 may contact the inner surface 70 of the induction coil 70. The distance between the outer surface 91 of the diverter body 90 and the bottom of the grooves 132, 134 of spacer ribs 101, 103 may be substantially the same as the distance between the outer surface 91 of the diverter body 90 and the radially outward facing surfaces 136, 138 of spacer ribs 102, 104. As such, when the airflow diverter 80 is mounted inside the induction coil 70, the central axis A-A of the induction coil 70 and the central axis B-B of the diverter body 90 may be substantially aligned, and the diverter body 90 may be centrally located within the central coil cavity 73 of the induction coil 70. In some embodiments, a distance between the inner surface 79 of the induction coil 70 and the outer surface 91 of the diverter body 90 (or the annulus radius of the annular gap 65 between the inner surface 79 of the induction coil 70 and the outer surface 91 of the diverter body 90) may range from about 0.125 inches to about 0.200 inches—including all values and sub-ranges thereof.

With continued reference to FIGS. 4, 8 and 9, in some embodiments, spacer ribs 101, 103 may extend radially from the outer surface 91 of the diverter body 90 in opposite directions. A transverse distance between the bottom of the grooves 132 formed in spacer rib 101 and the bottom of the grooves 134 formed in the spacer rib 103 may substantially correspond to an inner diameter of the induction coil 70. In some embodiments, spacer ribs 102, 104 may extend radially from the outer surface 91 of the diverter body 90 in opposite directions. A transverse distance between the radially outward facing surfaces 136, 138 of spacer ribs 102, 104 may substantially correspond to the inner diameter of the induction coil 70. Spacer ribs 101, 103 and spacer ribs 102, 104 may be spaced apart by an angle of rotation of about 90°. In some embodiments, the spacer ribs 101, 102, 103, 104 may be spaced apart by any suitable angle of rotation and/or may not extend in radially opposite directions. Four spacer ribs 101, 102, 103, 104 are shown. However, the airflow diverter 80 may include less than four or more than four spacer ribs.

### Removable Spacer

In some embodiments, the spacer ribs 101, 102, 103, 104 and the diverter body 90 may form as an integral part. In some embodiments, the spacer ribs 101, 102, 103, 104 may be formed as a separate part or parts from the diverter body 90.

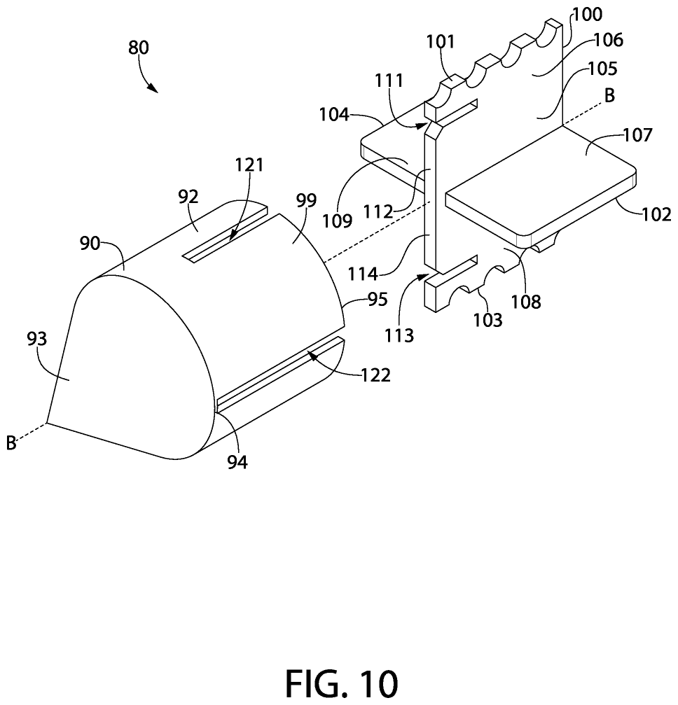

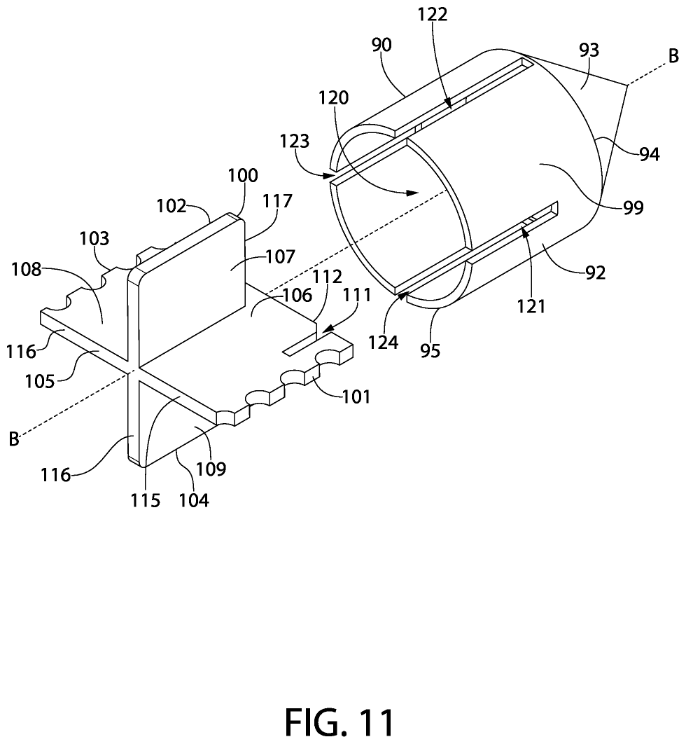

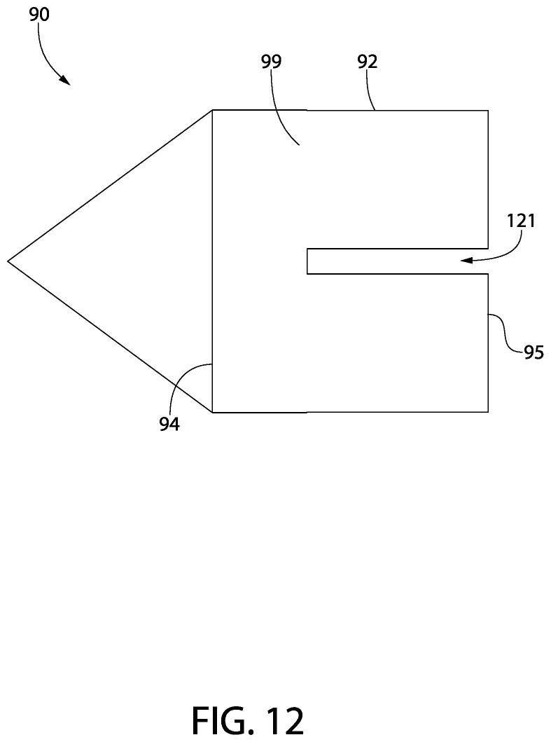

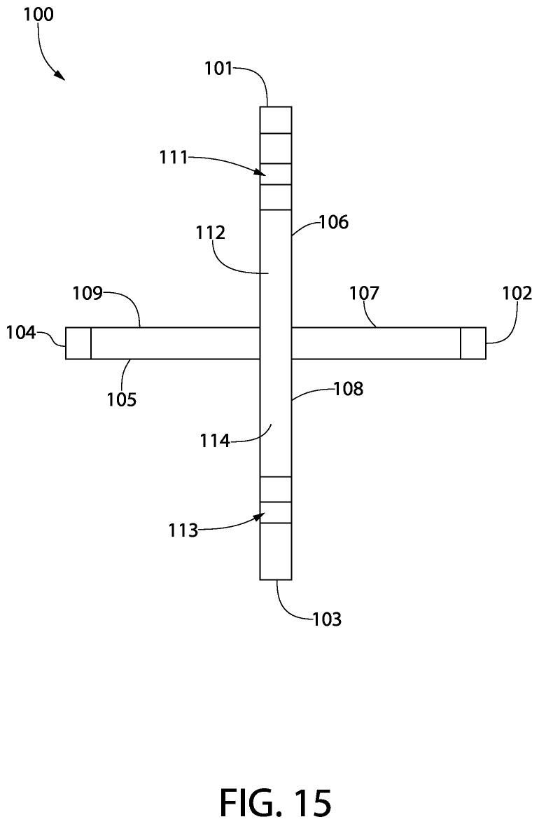

FIG. 10 shows a front exploded view of the airflow diverter 80 according to some embodiments. FIG. 11 shows a rear exploded view of the airflow diverter 80 that is rotated by 90° from FIG. 10. In the embodiment shown in FIGS. 10 and 11, the airflow diverter 80 may include a spacer 100 that may be removably coupled to the diverter body 90. The spacer 100 may include a spacer base 105 and the spacer ribs 101, 102, 103, 104 extending radially outward from the spacer base 105. FIGS. 12, 13, and 14 show additional views, specifically, top, right, and rear views of the diverter body 90, respectively. FIGS. 15, 16, and 17 show additional views, specifically, front, top, and right views of the spacer 100, respectively.

With reference to FIGS. 10, 11, 15, 16, and 17, in some embodiments, the spacer base 105 may have a transverse cross-sectional profile that may be in the form of a cross. The cruciform spacer base 105 may include arms 106, 107, 108, 109 extending radially outward from the central axis B-B of the diverter body 90. The spacer ribs 101, 102, 103, 104 may form extensions of the arms 106, 107, 108, 109. The arms 106, 107, 108, 109 may be formed in pairs, and each pair of arms may extend in opposite directions. For example, arm 106 and arm 108 may extend in opposite radial directions, and arm 107 and arm 109 may extend in opposite radial directions.

In some embodiments, the spacer 100 may be formed as a unitary or integral body, which may provide added stability for the airflow diverter 80 inside the induction coil 70. In some embodiments, one or more of the spacer ribs 101, 102, 103, 104 and/or the arms 106, 107, 108, 109 may be formed as separate, individual components that may be assembled together. In some embodiments, arms 106, 108, as well as spacer ribs 101, 103, may be formed as a unitary body which may be in a plate form. Arms 107, 109, as well as spacer ribs 102, 104, may be formed as a unitary body which may also be in a plate form. The two plates may each include an interlocking slot for receiving a portion of the other plates and form the cruciform spacer 100.

Although a cruciform spacer base 105 is described as an example, the spacer base 105 may take any suitable shapes or forms. In some embodiments, the spacer base 105 may include more or less than four arms. The spacer base 105 may include two, three, five, or more arms radially extending outward from the central axis B-B of the diverter body 90. In some embodiments, each of the arms may include a spacer rib. In some embodiments, only select arms may include a spacer rib. In some embodiments, instead of radially extending arms, the spacer base 105 may be in the form of a cylindrical, tubular, polygonal, or any three-dimensional body that may be received inside the main portion 92 of the diverter body 90. The spacer ribs 101, 102, 103, 104 may extend from an outer surface of the three-dimensional body of the spacer base 105 to mount and support the diverter body 90 within the central coil cavity 73 of the induction coil 70.

With reference to FIGS. 10-14, in some embodiments, the main portion 92 of the diverter body 90 may be in the form of a pipe and may include a wall 99 defining a central cavity 120 extending between the distal end 95 and the proximal end 94 of the main portion 92. Thus, in some embodiments, the distal end 95 of the main portion 92 may define an open end and the proximal end 94 of the main portion 92 may define a closed end. In some embodiments, the proximal end 94 of the main portion 92 may also define an open end such as in the case where the tapered portion 93 may also include a central cavity. The spacer base 105 or at least a portion thereof may be received inside the central cavity 120 of the main portion 92 of the diverter body 90.

In some embodiments, the wall 99 of the main portion 92 of the diverter body 90 may include slots 121, 122, 123, 124 formed therein extending from the distal end 95 of the main portion 92 toward the proximal end 94 of the main portion 92. In some embodiments, one or more of the slots 121, 122, 123, 124 may extend substantially the entire distance between the proximal end 94 and the distal end 95 of the main portion 92. In some embodiments, one or more of the slots 121, 122, 123, 124 may extend only a portion of the distance between the proximal end 94 and the distal end 95 of the main portion 92. The extension of the slots 121, 122, 123, 124 may be substantially parallel to the central axis B-B of the diverter body 90. Each of the slots 121, 122, 123, 124 may be configured to receive a portion of the spacer 100, such as a portion of each of the arms 106, 107, 108, 109 of the spacer 100 from which the spacer ribs 101, 102, 103, 104 further extend.

In some embodiments, one or more of the arms 106, 107, 108, 109, such as arms 106, 108, may also include slots 111, 113 formed in a leading edge 112, 114 of each arm 106, 108. The slots 111, 113 of arms 106, 108 may extend from the respective leading edges 112, 114 of arms 106, 108 towards a trailing edge 115, 116 of each of arms 106, 108. The slots 111, 113 of the arms 106, 108 may be configured to receive a portion of the wall 99 of the main portion 92 when the spacer 100 is placed inside the central cavity 120 of the main portion 92 of the diverter body 90. In some embodiments, arms 107, 109 may also include slots formed at the respective leading edge 117, 118 thereof and may be configured to receive a portion of the wall 99 of the main portion 92.

To couple the spacer 100 to the diverter body 90, the spacer 100 may be inserted through the opening at the distal end 95 of the main portion 92 into the central cavity 120 of the main portion 92 of the diverter body 90 by sliding each of the arms 106, 107, 108, 109 into a corresponding slot of the slots 121, 122, 123, 124. When the spacer 100 is fully inserted, the closed ends of slots 121, 123 in the wall 99 of the main portion 92 and the closed ends of slots 111, 113 in arms 106, 108 of the spacer 100 may be in an abutting relationship, and the closed ends of slots 122, 124 in the wall 99 of the main portion 92 and the leading edges 117, 118 of arms 107, 109 may be in an abutting relationship. Once the spacer 100 is inserted into the central cavity 120 of the main portion 92 of the diverter body 90, relative rotational movement between the spacer 100 and the diverter body 90 may be limited, and relative radially movement between the spacer 100 and the diverter body 90 may also be limited.

The slots 121, 122, 123, 124 in the wall 99 of the main portion 92 and/or the slots 111, 113 in the arms 106, 108 of the spacer 100 may be formed such that the diverter body 90 and the spacer 100 may be axially moved relative to each other, while the spacer 100 and the diverter body 90 may be rotationally and/or radially interlocked with each other.

In some embodiments, the slots 121, 122, 123, 124 formed in the wall 99 of the main portion 92 may each have a slot width that may substantially correspond to, or may be slightly greater than, a thickness of one of the arms 106, 107, 108, 109 to be received therein. In some embodiments, the slots 111, 113 formed in the arms 106, 108 of the spacer 100 may each have a slot width that may substantially correspond to, or may be slightly greater than, a thickness of the wall 99 of the main portion 92. The width of each slot 111, 113, 121, 122, 123, 124 may be defined by a distance between opposing side walls of each slot 111, 113, 121, 122, 123, 124.

In some embodiments, the width of each of the slots 121, 122, 123, 124 may be greater than the thickness of the arm 106, 107, 108, 109 to be received therein by about 20% or less, about 10% or less, or about 5% or less of the thickness of the corresponding arm 106, 107, 108, 109. In some embodiments, the width of each of the slots 111, 113 may be greater than the thickness of the wall 99 of the main portion 92 by about 20% or less, about 10% or less, or about 5% or less of the thickness of the wall 99 of the main portion 92.

In some embodiments, the thickness of each of the arms 106, 107, 108, 109 of the spacer 100 may range from about 0.10 inches to about 0.25 inches—including all values and sub-ranges thereof. The thickness of the wall of the main portion 92 of the diverter body 90 may range from about 0.10 inches to about 0.25 inches—including all values and sub-ranges thereof. The width of each of the slots 111, 113, 121, 122, 123, 124 may range from about 0.10 inches to about 0.25 inches—including all values and sub-ranges thereof.

As mentioned above, due to the large open space in the center of the induction coil 70, effectively cooling cannot be achieved conventionally because most of the cooling air flows through the central coil cavity 73 of the induction coil 70 without removing the heat generated around the metal surface of the induction coil 70.

In contrast, by positioning the airflow diverter 80 within the central coil cavity 73 of the induction coil 70, an incoming airflow stream may be prohibited by the diverter body 90 of the airflow diverter 80 from flowing through the central region 76 of the central coil cavity 73 of the induction coil 70. By positioning the induction coil apparatus 60 within the airflow stream so that the first open end 74 of the induction coil 70 may be upstream of the second open end 75 of the induction coil 70 and the tapered portion 93 of the airflow diverter 80 may protrude outward from the first open end 74, the airflow stream may be diverted from the central axis A-A of the induction coil 70 radially outward into the outer region 77 of the central coil cavity 73 and over the induction coil 70 to achieve effective cooling of the induction coil 70.

Additionally, because the flow of the airflow stream may be constricted due to the presence of the diverter body 90 within the central coil cavity 73 of the induction coil 70, the velocity of the airflow stream within the outer region 77 of the central coil cavity 73 may be greater than the velocity of the airflow stream upstream of the airflow diverter 80. The airflow stream may pass the surface of the induction coil 70 where the heat is generated at a relatively high velocity, reducing the operating temperature of the induction coil 70 significantly.

### Turbulator Features

Without the airflow diverter 80, the airflow stream through the central coil cavity 73 of the induction coil 70 may be substantially laminar. By placing the airflow diverter 80 within the central region 76 of the central coil cavity 73, the airflow stream through the outer region 77 of the central coil cavity 73 may be turbulent instead of laminar, thereby further improving the cooling effectiveness. In some embodiments, the airflow diverter 80 may further include one or more turbulator features on the outer surface 91 of the diverter body 90. The turbulator features may be configured to further induce turbulence in the airflow stream flowing through the outer region 77 of the central coil cavity 73.

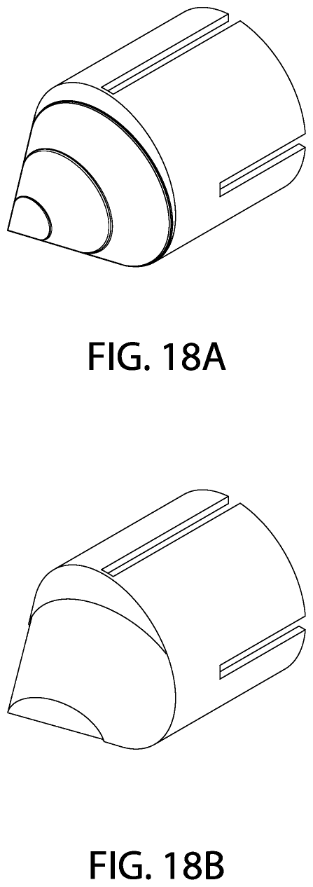

With reference to FIGS. 18A and 18B, in some embodiments, the one or more turbulator features may include at least one of a helical ridge and/or a helical depression. In some embodiments, the helical ridge and/or helical depression may wrap around the diverter body 90. In some embodiments, the helical ridge and/or helical depression may wrap around at least a portion of the tapered portion 93 of the diverter body 90, which may create rotation of the airflow stream, resulting in a more turbulent airflow stream. In some embodiments, the helical ridge and/or helical depression may wrap around at least a portion of the main portion 92 of the diverter body 90, in addition to or as an alternative to wrapping around the tapered portion 93 of the diverter body 90.

With reference to FIG. 18C, in some embodiments, the one or more turbulator features may include a roughened surface. In some embodiments, at least a portion of the outer surface 91 of the diverter body 90 may be roughened. In some embodiments, at least a portion of the outer surface of the main portion 92 of the diverter body 90 may be roughened. In some embodiments, additionally or alternatively, at least a portion of the outer surface of the tapered portion 93 of the diverter body 90 may be roughened.

With reference to FIG. 18D, in some embodiments, the one or more turbulator features may include one or more protuberances or tabs. In some embodiments, the one or more protuberances or tabs may be disposed at the outer surface 91 of the diverter body 90. In some embodiments, the one or more protuberances or tabs may be disposed at the outer surface of the main portion 92 of the diverter body 90. In some embodiments, additionally or alternatively, the one or more protuberances or tabs may be disposed at the outer surface of the tapered portion 93 of the diverter body 90.

### Air Baffles

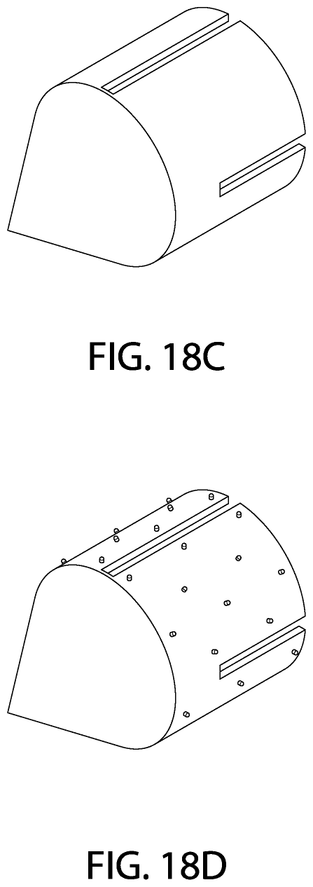

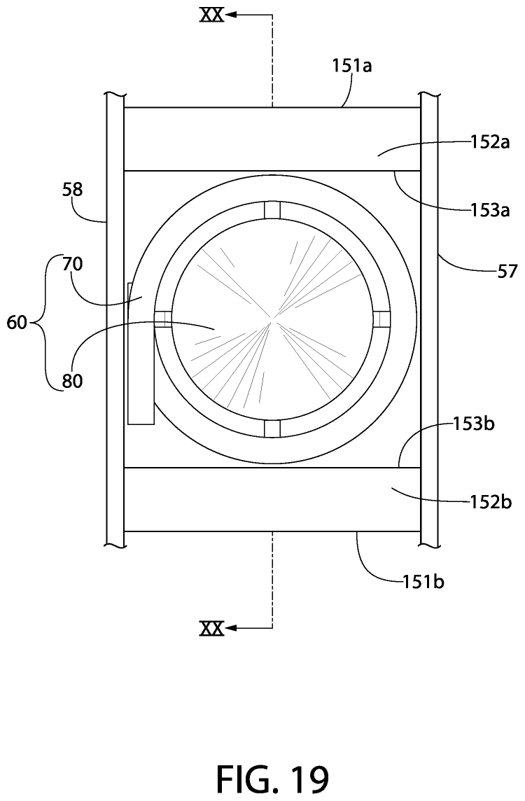

In some embodiments, the airflow guide may include one or more air baffles that may be used to further improve the cooling efficiency. With reference to FIG. 19, one or more air baffles 151a, 151b configured to direct the airflow stream toward the induction coil apparatus 60 are shown. FIG. 20 is a cross-sectional view along line XX-XX in FIG. 19, schematically illustrating the flow of the airflow stream around the induction coil 70.

In some embodiments, the air baffles 151a, 151b may be positioned adjacent to the induction coil apparatus 60 and outside of the induction coil apparatus 60. Referring to FIG. 19, in some embodiments, the air baffles 151a, 151b may be positioned adjacent to opposing walls 57, 58 of the housing 52 of the matching network 11. The air baffles 151a, 151b may extend from one of the housing walls 57, 58 to the other of the housing walls 57, 58. The width of the air baffles 151a, 151b may substantially correspond to the distance between the opposing housing walls 57, 58. The air baffles 151a, 151b and/or the housing walls 57, 58 may converge and/or confine the airflow stream to the space around the surface of the induction coil 70.

With reference to FIG. 20, in some embodiments, the air baffles 151a, 151b may each include a funnel section 152a 152b and a main section 153a 153b. The funnel sections 152a 152b may be configured to converge the airflow stream about the induction coil 70. The main sections 153a 153b may extend adjacent to and along a length of the induction coil 70 to maintain the converged airflow stream about the induction coil 70. The main sections 153a 153b of the air baffles 151a, 151b and the diverter body 90 of the airflow diverter 80 may cooperate and constrict the turbulent flow of the airflow stream around the surface of the induction coil 70. By utilizing the airflow diverter 80 and/or the air baffles 151a, 151b, effective coil cooling and operating temperature reduction may be achieved without the use of larger fans, coils, and/or housing, which may allow for a more compact design of the matching network 11.

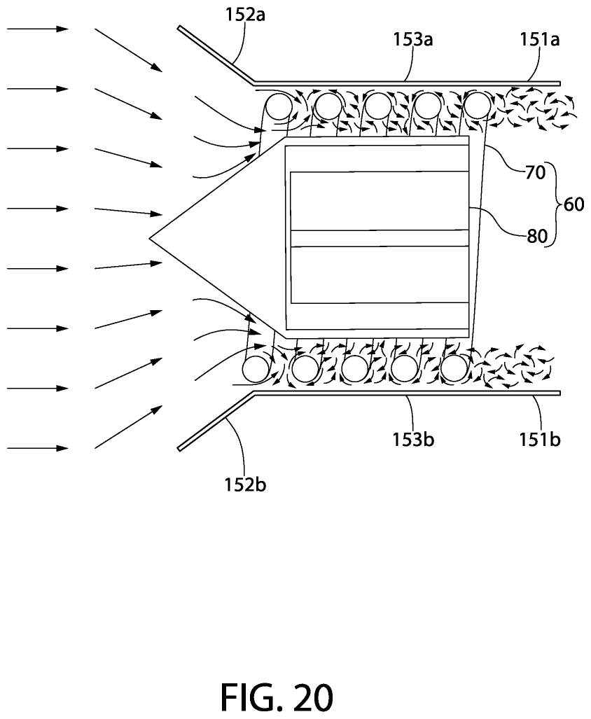

Referring to FIGS. 19 and 20, in some embodiments, the funnel sections 152a, 152b and/or the main sections 153a 153b of the air baffles 151a, 151b may be in the form of a substantially flat or straight plate. Referring to FIG. 21, in some embodiments, air baffles 154a, 154b having curved sections may be implemented. Each of the air baffles 154a, 154b may include a curved funnel section 155a, 155a and/or a curved main section 156a, 156b. The funnel sections 155a, 155a of the air baffles 154a, 154b may each be in the form of a portion of a truncated cone. The main sections 156a, 156b of the air baffles 154a, 154b may each be in the form of a portion of a cylindrical pipe. The main sections 156a, 156b of the air baffles 154a, 154b, the diverter body 90 of the airflow diverter 80, and/or the induction coil 70 may be concentric.

In some embodiments, the one or more air baffles may be placed around portions of the induction coil 70 to converge and compress the airflow stream around the surface of the induction coil 70, such as the air baffles 151a, 151b shown in FIG. 19 or the air baffles 154a, 154b shown in FIG. 21 which may be positioned on opposite sides of the induction coil 70. The one or more air baffles and the housing walls of matching network 11 may cooperate and converge the airflow stream around the surface of the induction coil 70.

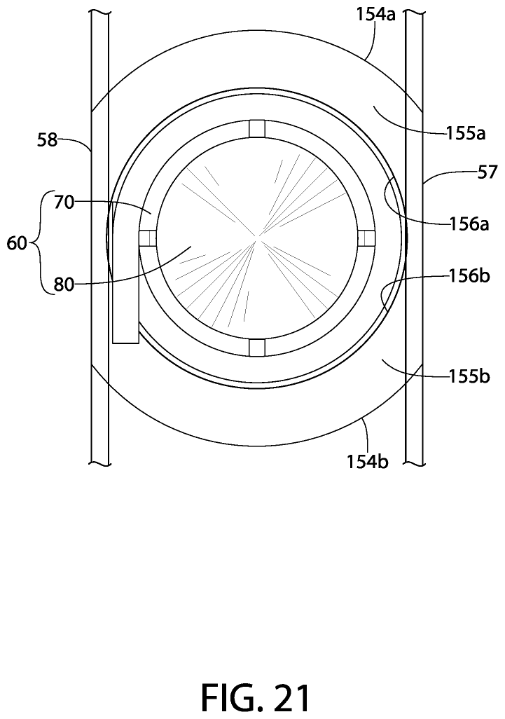

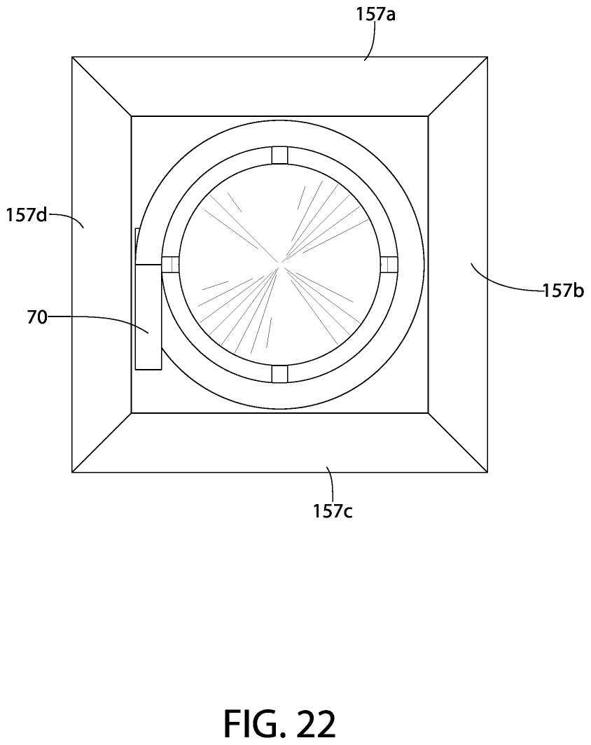

In some embodiments, depending on the design of the matching network 11, the one or more air baffles may be placed around the entire outer surface of the induction coil 70. Referring to FIG. 22, in some embodiments, air baffles 157a, 157b, 157c, 157d may be positioned around the entire outer surface of the induction coil 70, forming an enclosure around the induction coil 70. Although four air baffles 157a, 157b, 157c, 157d are shown in FIG. 22, less than four or more than four air baffles may be utilized to form an enclosure around the induction coil 70. In some embodiments, the air baffle surrounding the induction coil 70 may be formed as a unitary body, such as the air baffle 158 shown in FIGS. 23A, 23B. In some embodiments, the air baffles 157a, 157b, 157c, 157d shown in FIG. 22 may also be formed as one unitary or integral body.

In some embodiments, the air baffles may be positioned around the induction coil 70 without contacting the induction coil 70. In other words, a gap between an inner surface of the main section of the air baffle and the outer surface of the induction coil 70 may be maintained. In some embodiments, the distance between the inner surface of the main section of the air baffle and the outer surface of the induction coil 70 may range from about 0.05 inches to about 0.50 inches—including all values and sub-ranges thereof.

The airflow diverter 80 and/or the air baffles may be manufactured via molding (e.g., injection molding, compression molding, etc.), additive manufacturing (e.g., 3D printing), casting, machining, or any other suitable manufacturing methods. Materials used for forming the airflow diverter 80 and/or the air baffles may be selected such that the airflow diverter 80 and/or the air baffles may withstand high temperature and/or high voltage. The materials used for forming the airflow diverter 80 and/or the air baffles may generally be insulators. In some embodiments, the materials used for forming the airflow diverter 80 and/or air baffles may include plastic (e.g., resins, glass-filled polymers, including but not limited to glassed filled nylons, etc.), ceramic, and the like. One exemplary material for forming the airflow diverter 80 and/or air baffles may include Somos® PerFORM from Covestro AG.

With the use of the airflow diverter 80, the operating temperature of the induction coil 70 may be reduced by at least 10° C. when compared to the induction coil 70 operating without the airflow diverter 80. When the airflow diverter 80 and air baffles may be used together, the operating temperature of the induction coil 70 may be further reduced by at least 20° C. when compared to the induction coil 70 operating with the airflow diverter 80 alone.

### Method of Cooling Induction Coil

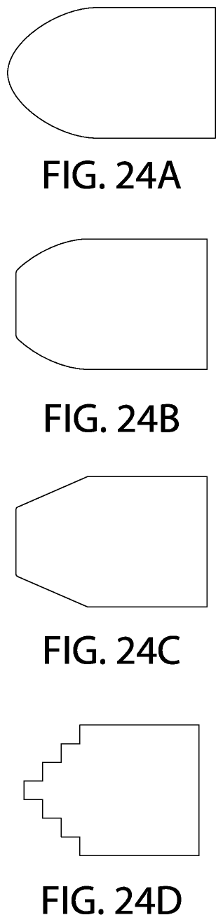

FIG. 25 is a flow chart showing a method 200 of cooling the induction coil 70 according to some embodiments. At step 201, an airstream flow may be generated. In some embodiments, the airstream flow may be generated using the airflow generator 25 described herein. At step 202, at least a portion of the airstream flow may be directed over the induction coil 70. In some embodiments, the portion of the airstream flow may be directed over the induction coil 70 using the airflow guide described herein. In some embodiments, the airflow guide may include an airflow diverter, such as the airflow diverter 80 described herein, or one or more air baffles, such as the various air baffles described herein, or a combination of both.

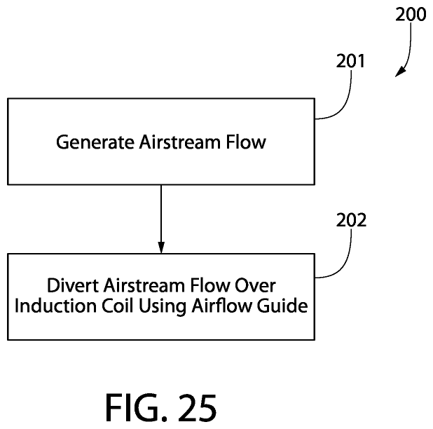

FIG. 26 is a flow chart showing a method 300 of cooling the induction coil 70 according to some embodiments. At step 301, an airstream flow may be generated toward the induction coil apparatus 60. The airstream flow may be generated using the airflow generator 25 described herein. The airflow generator 25 may be configured such that the tapered portion 93 of the diverter body 90 of the airflow diverter 80 may be upstream of the main portion 92 of the diverter body 90.

At step 302, at least a portion of the airstream flow may be diverted radially outward from the central axis A-A of the induction coil 70 such that the portion of the airstream flow may flow through the outer region 77 of the central coil cavity 73 and over the induction coil 70 for cooling the induction coil 70 and/or reducing the operating temperature of induction coil 70. In some embodiments, the portion of the airstream flow may be diverted radially outward from the central axis A-A of the induction coil 70 using, for example, the airflow diverter 80 described herein.

### Method of Mounting Airflow Diverter

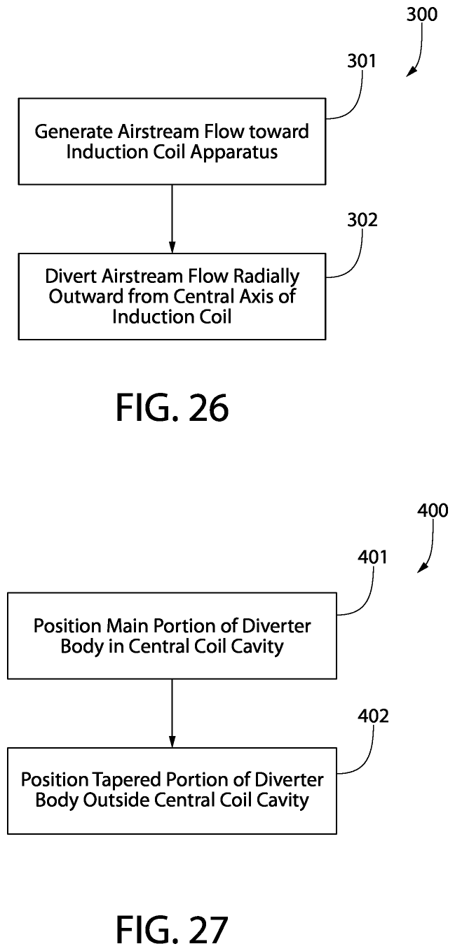

FIG. 27 is a flow chart showing a method 400 of mounting the airflow diverter 80 to the induction coil 70 according to some embodiments. At step 401, the main portion 92 of the diverter body 90 of the airflow diverter 80 may be positioned into the central coil cavity 73, e.g., the central region 76 of the central coil cavity 73 of the induction coil 70. At step 402, the tapered portion 93, or at least a portion there, of the diverter body 90 of the airflow diverter 80 may be positioned outside the central coil cavity 73 of the induction coil 70 such that the tapered portion 93 may protrude outward from the first open end 74 of the central coil cavity 73.

In some embodiments, in the case where the diverter body 90 and the spacer ribs 101, 102, 103, 104 may be formed as a unitary body, the main portion 92 of the diverter body 90 may be positioned into the central coil cavity 73 of the induction coil 70 by rotatably coupling one or more of the spacer ribs 101, 103 to the induction coil 70 while moving the diverter body 90 along the central axis A-A of the induction coil 70.

In some embodiments, in the case where the diverter body 90 and the spacer ribs 101, 102, 103, 104 may be formed as separate components, the method may further include, prior to positioning the main portion 92 of the diverter body 90 into the central coil cavity 73 of the induction coil 70, coupling the spacer 100 to the induction coil 70. The spacer 100 may be coupled to the induction coil 70 by rotatably coupling one or more of the spacer ribs 101, 103 of the spacer 100 to the induction coil 70 while moving the spacer 100 along the central axis A-A of the induction coil 70. Positioning the main portion 92 of the diverter body 90 into the central coil cavity 73 of the induction coil 70 may include coupling the main portion 92 of the diverter body 90 to the spacer 100. In some embodiments, the diverter body 90 may be coupled to the spacer 100 prior to positioning the main portion 92 of the diverter body 90 into the central coil cavity 73 of the induction coil 70.

While the foregoing description and drawings represent exemplary embodiments of the present disclosure, it will be understood that various additions, modifications and substitutions may be made therein without departing from the spirit and scope and range of equivalents of the accompanying claims. In particular, it will be clear to those skilled in the art that the present invention may be embodied in other forms, structures, arrangements, proportions, sizes, and with other elements, materials, and components, without departing from the spirit or essential characteristics thereof. In addition, numerous variations in the methods/processes described herein may be made within the scope of the present disclosure. One skilled in the art will further appreciate that the embodiments may be used with many modifications of structure, arrangement, proportions, sizes, materials, and components and otherwise, used in the practice of the disclosure, which are particularly adapted to specific environments and operative requirements without departing from the principles described herein. The presently disclosed embodiments are therefore to be considered in all respects as illustrative and not restrictive. The appended claims should be construed broadly, to include other variants and embodiments of the disclosure, which may be made by those skilled in the art without departing from the scope and range of equivalents.

### Exemplary Claim Set

Exemplary claim 1. A radio frequency (RF) matching system comprising: an airflow generator configured to generate an airflow stream; an induction coil apparatus positioned within the airflow stream to be generated by the airflow generator, the induction coil apparatus comprising: an induction coil; and an airflow guide positioned and configured to direct the airflow stream to be generated by the airflow generator over the induction coil.

Exemplary claim 2. The RF matching system according to Exemplary claim 1 wherein the airflow generator is downstream of the induction coil apparatus in the airflow stream to be generated by the airflow generator.

Exemplary claim 3. The RF matching system according to Exemplary claim 1 wherein the airflow generator is upstream of the induction coil apparatus in the airflow stream to be generated by the airflow generator.

Exemplary claim 4. The RF matching system according to any one of Exemplary claims 1 to 3 wherein: the induction coil defines a central coil cavity, the central coil cavity extending along a central axis from a first open end to a second open end, the first open end being upstream of the second open end in the airstream flow to be generated by the airflow generator, the central coil cavity having a central region located along the central axis and an outer region adjacent the induction coil and circumferentially surrounding the central region; and the airflow guide comprises an airflow diverter positioned within the central region of the central coil cavity of the induction coil, the airflow diverter configured to divert the airflow stream radially outward from the central axis and into the outer region.

Exemplary claim 5. The RF matching system according to Exemplary claim 4 wherein the airflow diverter is configured to prohibit the airflow stream from flowing through the central region of the central coil cavity.

Exemplary claim 6. The RF matching system according to any one of Exemplary claims 4 to 5 wherein the velocity of the airflow stream upstream of the airflow diverter is less than the velocity of the airflow stream within the outer region of the central coil cavity.

Exemplary claim 7. The RF matching system according to any one of Exemplary claims 4 to 6 wherein the airflow diverter comprises a diverter body.

Exemplary claim 8. The RF matching system according to Exemplary claim 7 wherein the diverter body comprises a tapered portion terminating in a distal tip.

Exemplary claim 9. The RF matching system according to Exemplary claim 8 wherein the tapered portion of the diverter body comprises a cross-sectional profile that decreases in size moving from a proximal end of the tapered portion toward the distal tip.

Exemplary claim 10. The RF matching system according to Exemplary claim 9 wherein the cross-sectional profile of the tapered portion of the diverter body is symmetric about the central axis of the central coil cavity.

Exemplary claim 11. The RF matching system according to any one of Exemplary claims 8 to 10 wherein the tapered portion of the diverter body is in the form of a cone or a dome.

Exemplary claim 12. The RF matching system according to any one of Exemplary claims 8 to 11 wherein the diverter body further comprises a main portion, the tapered portion extending from the main portion.

Exemplary claim 13. The RF matching system according to Exemplary claim 12 wherein the main portion has a substantially constant transverse cross-sectional profile.

Exemplary claim 14. The RF matching system according to Exemplary claim 13 wherein the transverse cross-sectional profile of the main portion is symmetric about the central axis of the central coil cavity.

Exemplary claim 15. The RF matching according to any one of Exemplary claims 12 to 14 wherein the main portion of the diverter body is located between the first and second open ends of the central coil cavity.

Exemplary claim 16. The RF matching system according to any one of Exemplary claims 8 to 15 wherein the tapered portion of the diverter body protrudes outward from the first open end of the central coil cavity.

Exemplary claim 17. The RF matching system according to any one of Exemplary claims 7 to 15 wherein the airflow diverter is mounted within the induction coil so that an annular gap exists between an outer surface of the diverter body and an inner surface of the induction coil.

Exemplary claim 18. The RF matching system according to Exemplary claim 17 wherein the airflow diverter is mounted to and supported by the induction coil.

Exemplary claim 19. The RF matching system according to any one of Exemplary claims 17 to 18 wherein the airflow diverter further comprises a plurality of spacer ribs protruding from the outer surface of the diverter body, one or more of the plurality of spacer ribs configured to contact the inner surface of the induction coil to maintain the annular gap.

Exemplary claim 20. The RF matching system according to Exemplary claim 19 wherein one or more of the spacer ribs are configured to axially retain the airflow diverter within the induction coil through mechanical interference with the induction coil.

Exemplary claim 21. The RF matching system according to Exemplary claim 20 wherein the one or more spacer ribs configured to axially retain the airflow diverter within the induction coil comprise one or more protuberances that extend into a space between adjacent coil turns of the induction coil.

Exemplary claim 22. The RF matching system according to Exemplary claim 21 wherein grooves are formed between adjacent ones of the protuberances; and wherein the induction coil nests within the grooves.

Exemplary claim 23. The RF matching system according to any one of Exemplary claims 19 to 22 wherein each of the plurality of spacer ribs extend along a rib axis that is substantially parallel to the central axis.

Exemplary claim 24. The RF matching system according to any one of Exemplary claims 7 to 23 wherein the airflow diverter further comprises one or more turbulator features on the outer surface of the diverter body that are configured to induce turbulence in the airflow stream that flows through the outer region of the central coil cavity.

Exemplary claim 25. The RF matching system according to Exemplary claim 24 wherein the one or more turbulator features comprise at least one of a helical ridge that wraps around the diverter body, a helical depression that wraps around the diverter body, a roughened surface, or a plurality of protuberances or tabs.

Exemplary claim 26. The RF matching system according to any one of Exemplary claims 4 to 25 wherein a helical space exists between adjacent coil turns of the induction coil, the helical space in spatial communication with the outer region of the central coil cavity.

Exemplary claim 27. The RF matching system according to any one of Exemplary claims 4 to 26 wherein the induction coil is mounted in a floating arrangement.

Exemplary claim 28. The RF matching system according to any one of Exemplary claims 1 to 27 wherein: the airflow guide comprises one or more air baffles mounted adjacent to and outside of the induction coil apparatus and configured to direct the airflow stream toward the induction coil.

Exemplary claim 29. The RF matching system according to Exemplary claim 28 wherein the one or more baffles comprise a funnel section that converges the airflow stream to be generated by the airflow generator about the induction coil.

Exemplary claim 30. The RF matching system according to Exemplary claim 29 wherein the one or more baffles comprise a main section that extends adjacent to and along a length of the induction coil to maintain the converged airflow stream about the induction coil.

Exemplary claim 31. The RF matching system according to any one of Exemplary claims 1 to 30 further comprising: a housing comprising an inlet vent and an outlet vent; the induction coil apparatus disposed within the housing; and the airflow generator located outside of the housing and configured to generate the airflow stream so that the airflow stream enters the housing via the inlet vent, flows over the induction coil apparatus, and exits the housing via the outlet vent.

Exemplary claim 32. The RF matching system according to Exemplary claim 31 further comprising a plurality of the induction coil apparatus disposed within the housing.

Exemplary claim 33. The RF matching system according to any one of Exemplary claims 1 to 32 wherein the airflow guide is positioned and configured to direct the airflow stream to be generated by the airflow generator radially through a helical space that exists between adjacent coil turns of the induction coil.

Exemplary claim 34. An induction coil apparatus for use in a radio frequency matching network comprising: an induction coil; and an airflow guide configured to direct an incoming airflow stream over the induction coil.

Exemplary claim 35. The induction coil apparatus according to Exemplary claim 34 wherein the airflow guide is configured to be mounted to the induction coil.

Exemplary claim 36. The induction coil apparatus according to any one of Exemplary claims 34 to 35 wherein: the induction coil defines a central coil cavity, the central coil cavity extending along a central axis from a first open end to a second open end, the central coil cavity having a central region located along the central axis and an outer region adjacent the induction coil and circumferentially surrounding the central region; and the airflow guide comprises an airflow diverter positioned within the central portion of the central coil cavity of the induction coil, the airflow diverter configured to divert an incoming airflow stream radially outward from the central axis and into the outer region.

Exemplary claim 37. The induction coil apparatus according to Exemplary claim 36 wherein the airflow diverter is configured to prohibit the incoming airflow stream from flowing through the central region of the central coil cavity.

Exemplary claim 38. The induction coil apparatus according to any one of Exemplary claims 36 to 37 wherein the airflow diverter comprises a diverter body comprising: a tapered portion terminating in a distal tip; and a main portion, the tapered portion extending from the main portion.

Exemplary claim 39. The induction coil apparatus according to Exemplary claim 38 wherein the tapered portion of the diverter body comprises a cross-sectional profile that decreases in size moving from the main portion toward the distal tip of the tapered portion.

Exemplary claim 40. The induction coil apparatus according to any one of Exemplary claims 38 to 39 wherein the main portion has a substantially constant transverse cross-sectional profile.

Exemplary claim 41. The induction coil apparatus according to Exemplary claim 40 wherein the cross-sectional profiles of the tapered portion and the main portion are symmetric about the central axis of the central coil cavity.

Exemplary claim 42. The induction coil apparatus according to any one of Exemplary claims 38 to 41 wherein the tapered portion of the diverter body is in the form of a cone or a dome.

Exemplary claim 43. The induction coil apparatus according to any one of Exemplary claims 38 to 42 wherein the main portion of the diverter body is located between the first and second open ends of the central coil cavity; and the tapered portion of the diverter body protrudes outward from the first open end of the central coil cavity.

Exemplary claim 44. The induction coil apparatus according to any one of Exemplary claims 38 to 43 wherein the airflow diverter is mounted within the induction coil so that an annular gap exists between an outer surface of the diverter body and an inner surface of the induction coil.

Exemplary claim 45. The induction coil apparatus according to Exemplary claim 44 wherein the airflow diverter is mounted to and supported by the induction coil.

Exemplary claim 46. The induction coil apparatus according to any one of Exemplary claims 38 to 45 wherein the airflow diverter further comprises a plurality of spacer ribs protruding from the outer surface of the diverter body, one or more of the plurality of spacer ribs configured to contact the inner surface of the induction coil to maintain the annular gap.

Exemplary claim 47. The induction coil apparatus according to Exemplary claim 46 wherein one or more of the spacer ribs are configured to axially retain the airflow diverter within the induction coil through mechanical interference with the induction coil.

Exemplary claim 48. The induction coil apparatus according to any one of Exemplary claims 38 to 47 wherein the airflow diverter further comprises one or more turbulator features on the outer surface of the diverter body that are configured to induce turbulence in the airflow stream that flows through the outer region of the central coil cavity.

Exemplary claim 49. The induction coil apparatus according to Exemplary claim 48 wherein the one or more turbulator features comprise at least one of a helical ridge that wraps around the diverter body, a helical depression that wraps around the diverter body, a roughened surface, or a plurality of protuberances or tabs.

Exemplary claim 50. The induction coil apparatus according to any one of Exemplary claims 34 to 49 wherein the airflow guide comprises one or more air baffles configured to direct the airflow stream toward the induction coil.

Exemplary claim 51. The induction coil apparatus according to Exemplary claim 50 wherein the one or more air baffles comprise a funnel section that converges the airflow stream to be generated by the airflow generator about the induction coil.

Exemplary claim 52. The RF matching system according to Exemplary claim 51 wherein the one or more baffles comprise a main section that extends adjacent to and along a length of the induction coil to maintain the converged airflow stream about the induction coil.

Exemplary claim 53. An airflow diverter for cooling an induction coil in a radio frequency matching network comprising: a diverter body configured to be positioned in a central coil cavity defined by an induction coil; and a plurality of spacer ribs protruding from an outer surface of the diverter body, wherein the plurality of spacer ribs is configured to mount the airflow diverter to the induction coil and is configured to maintain an annular gap between the outer surface of the diverter body and an inner surface of the induction coil.

Exemplary claim 54. The airflow diverter according to Exemplary claim 53 wherein the diverter body is configured to prohibit an incoming airflow stream from flowing through a central region of the central coil cavity.

Exemplary claim 55. The airflow diverter according to any one of Exemplary claims 53 to 54 wherein the diverter body comprises a tapered portion terminating in a distal tip; and a main portion, the tapered portion extending from the main portion.

Exemplary claim 56. The airflow diverter according to Exemplary claim 55 wherein the tapered portion of the diverter body comprises a cross-sectional profile that decreases in size moving from the main portion toward the distal tip of the tapered portion.

Exemplary claim 57. The airflow diverter according to any one of Exemplary claims 55 to 56 wherein the main portion has a substantially constant transverse cross-sectional profile.

Exemplary claim 58. The airflow diverter according to Exemplary claim 57 wherein the cross-sectional profiles of the tapered portion and the main portion are symmetric about a central axis of the airflow diverter.

Exemplary claim 59. The airflow diverter according to any one of Exemplary claims 55 to 58 wherein the tapered portion of the diverter body is in the form of a cone or a dome.

Exemplary claim 60. The airflow diverter according to any one of Exemplary claims 55 to 59 wherein the main portion of the diverter body is configured to be positioned between a first open end and a second open end of the central coil cavity; and the tapered portion of the diverter body is configured to protrude outward from the first open end of the central coil cavity.

Exemplary claim 61. The airflow diverter according to any one of Exemplary claims 53 to 60 wherein one or more of the plurality of spacer ribs are configured to contact the inner surface of the induction coil to maintain the annular gap.

Exemplary claim 62. The airflow diverter according to Exemplary claims 53 to 61 wherein one or more of the plurality of spacer ribs are configured to axially retain the airflow diverter within the induction coil through mechanical interference with the induction coil.

Exemplary claim 63. The airflow diverter according to Exemplary claim 62 wherein the one or more spacer ribs configured to axially retain the airflow diverter within the induction coil comprise one or more protuberances that extend into a space between adjacent coil turns of the induction coil.

Exemplary claim 64. The airflow diverter according to Exemplary claim 63 wherein grooves are formed between adjacent ones of the protuberances; and wherein the grooves are configured to receive therein at least portions of the induction coil.

Exemplary claim 65. The airflow diverter according to any one of Exemplary claims 53 to 64 wherein each of the plurality of spacer ribs extend along a rib axis that is substantially parallel to a central axis of the airflow diverter.

Exemplary claim 66. The airflow diverter according to any one of Exemplary claims 53 to 62 further comprising one or more turbulator features on the outer surface of the diverter body that are configured to induce turbulence in the airflow stream that flows through the outer region of the central coil cavity.

Exemplary claim 67. The airflow diverter according to Exemplary claim 66 wherein the one or more turbulator features comprise at least one of a helical ridge that wraps around the diverter body, a helical depression that wraps around the diverter body, a roughened surface, or a plurality of protuberances or tabs.

Exemplary claim 68. The airflow diverter according to any one of Exemplary claims 53 to 67 wherein the plurality of spacer ribs is removably coupled to the diverter body.

Exemplary claim 69. The airflow diverter according to Exemplary claim 68 further comprising a spacer base, wherein the plurality of spacer ribs extending radially outward from the spacer base.

Exemplary claim 70. The airflow diverter according to any one of Exemplary claims 68 to 69 wherein the spacer base and the plurality of spacer ribs form one unitary body.

Exemplary claim 71. The airflow diverter according to any one of Exemplary claims 68 to 70 wherein the main portion of the diverter body comprises an open end opposite the tapered portion of the diverter body, at least a portion of the spacer base is receivable inside the main portion through the open end of the main portion.

Exemplary claim 72. The airflow diverter according to any one of Exemplary claims 68 to 71 wherein the spacer base and the main portion of the diverter body are axially movable relative to each other.

Exemplary claim 6473 The airflow diverter according to any one of Exemplary claims 68 to 71 wherein the spacer base and the main portion of the diverter body are rotationally interlocked with each other.

Exemplary claim 74. The airflow diverter according to any one of Exemplary claims 68 to 72 wherein the spacer base and the main portion of the diverter body are radially interlocked with each other.

Exemplary claim 75. The airflow diverter according to any one of Exemplary claims 68 to 73 wherein the spacer base comprises a plurality of arms extending radially outward from a central axis of the airflow diverter.

Exemplary claim 76. A method of cooling an induction coil in a radio frequency matching network, the method comprising: generating an airstream flow; and directing at least a portion of the airstream flow over the induction coil using an airflow guide.

Exemplary claim 77. A method of cooling an induction coil in a radio frequency matching network, the method comprising: a) generating an airstream flow toward an induction coil apparatus comprising the induction coil, the induction coil defining a central coil cavity that extends along a central axis; and b) diverting a portion of the airstream flow radially outward from the central axis so that the portion of the airstream flow flows through an outer region of the central coil cavity and over the induction coil rather than through a central region of the central coil cavity.

Exemplary claim 78. A method of mounting an airflow diverter comprising a diverter body to an induction coil in a radio frequency matching network, the method comprising: a) positioning at least a portion of a main portion of the diverter body of the airflow diverter into a central coil cavity of the induction coil, the central coil cavity extending along a central axis of the induction coil; and b) positioning at least a portion of a tapered portion of the diverter body of the airflow diverter outside the central coil cavity of the induction coil.

Exemplary claim 79. The method according to Exemplary claim 78, wherein the airflow diverter further comprises a plurality of spacer ribs protruding from an outer surface of the diverter body, wherein step a) comprises moving the diverter body along the central axis of the induction coil while rotatably coupling one or more of the plurality of spacer ribs to the induction coil.

Exemplary claim 80. The method according to Exemplary claim 78, wherein the airflow diverter further comprises a spacer, wherein the method further comprises, prior to step a), coupling the spacer to the induction coil, and wherein step a) comprises coupling the main portion of the diverter body to the spacer.

What is claimed is:

1. A radio frequency (RF) matching system comprising:
an airflow generator configured to generate an airflow stream;
an induction coil apparatus positioned within the airflow stream to be generated by the airflow generator, the induction coil apparatus comprising:
an induction coil; and
an airflow guide positioned and configured to direct the airflow stream to be generated by the airflow generator over the induction coil.

2. The RF matching system according to claim 1, wherein:
the induction coil defines a central coil cavity, the central coil cavity extending along a central axis from a first open end to a second open end, the first open end being upstream of the second open end in the airstream flow to be generated by the airflow generator, the central coil cavity having a central region located along the central axis and an outer region adjacent the induction coil and circumferentially surrounding the central region; and
the airflow guide comprises an airflow diverter positioned within the central region of the central coil cavity of the induction coil, the airflow diverter configured to divert the airflow stream radially outward from the central axis and into the outer region.

3. The RF matching system according to claim 2, wherein the airflow diverter is configured to prohibit the airflow stream from flowing through the central region of the central coil cavity.

4. The RF matching system according to claim 2, wherein a velocity of the airflow stream upstream of the airflow diverter is less than a velocity of the airflow stream within the outer region of the central coil cavity.

5. The RF matching system according to claim 1, wherein the airflow diverter comprises a diverter body comprising a tapered portion terminating in a distal tip, wherein the tapered portion of the diverter body comprises a cross-sectional profile that decreases in size moving from a proximal end of the tapered portion toward the distal tip.

6. The RF matching system according to claim 5, wherein the diverter body further comprises a main portion, the tapered portion extending from the main portion; and wherein the main portion has a substantially constant transverse cross-sectional profile.

7. The RF matching according to claim 6, wherein:
the main portion of the diverter body is located between the first and second open ends of the central coil cavity; and
the tapered portion of the diverter body protrudes outward from the first open end of the central coil cavity.

8. The RF matching system according to claim 5, wherein the airflow diverter is mounted within the induction coil so that an annular gap exists between an outer surface of the diverter body and an inner surface of the induction coil.

9. The RF matching system according to claim 5, wherein the airflow diverter further comprises a plurality of spacer ribs protruding from the outer surface of the diverter body, one or more of the plurality of spacer ribs configured to contact the inner surface of the induction coil to maintain the annular gap.

10. The RF matching system according to claim 9 wherein one or more of the spacer ribs are configured to axially retain the airflow diverter within the induction coil through mechanical interference with the induction coil.

11. The RF matching system according to claim 5, wherein the airflow diverter further comprises one or more turbulator features on the outer surface of the diverter body that are configured to induce turbulence in the airflow stream that flows through the outer region of the central coil cavity.

12. An induction coil apparatus for use in a radio frequency matching network comprising:
an induction coil; and
an airflow guide configured to direct an incoming airflow stream over the induction coil;
wherein:
the induction coil defines a central coil cavity, the central coil cavity extending along a central axis from a first open end to a second open end, the central coil cavity having a central region located along the central axis and an outer region adjacent the induction coil and circumferentially surrounding the central region; and
the airflow guide comprises an airflow diverter positioned within the central portion of the central coil cavity of the induction coil, the airflow diverter configured to divert an incoming airflow stream radially outward from the central axis and into the outer region.

13. The induction coil apparatus according to claim 12, wherein the airflow diverter is configured to prohibit the incoming airflow stream from flowing through the central region of the central coil cavity, and comprises a diverter body comprising: a tapered portion terminating in a distal tip; and a main portion, the tapered portion extending from the main portion.

14. The induction coil apparatus according to any one of claim 12, wherein the airflow diverter is mounted within the induction coil so that an annular gap exists between an outer surface of the diverter body and an inner surface of the induction coil, and wherein the airflow diverter further comprises a plurality of spacer ribs protruding from the outer surface of the diverter body, one or more of the plurality of spacer ribs configured to contact the inner surface of the induction coil to maintain the annular gap.

15. The induction coil apparatus according to claim 13, wherein the main portion has a substantially constant transverse cross-sectional profile, and wherein the cross-sectional profiles of the tapered portion and the main portion are symmetric about the central axis of the central coil cavity.

16. An airflow diverter for cooling an induction coil in a radio frequency matching network comprising:
a diverter body configured to be positioned in a central coil cavity defined by an induction coil; and
a plurality of spacer ribs protruding from an outer surface of the diverter body, wherein the plurality of spacer ribs is configured to mount the airflow diverter to the induction coil and is configured to maintain an annular gap between the outer surface of the diverter body and an inner surface of the induction coil.

17. The airflow diverter according to claim 16, wherein the diverter body comprises a tapered portion terminating in a distal tip; and a main portion, the tapered portion extending from the main portion, and wherein the main portion of the diverter body is configured to be positioned between a first open end and a second open end of the central coil cavity; and the tapered portion of the diverter body is configured to protrude outward from the first open end of the central coil cavity.

18. The airflow diverter according to claim 16, wherein one or more of the plurality of spacer ribs are configured to contact the inner surface of the induction coil to maintain the annular gap, and one or more of the plurality of spacer ribs are configured to axially retain the airflow diverter within the induction coil through mechanical interference with the induction coil.

19. The airflow diverter according to claim 16, wherein the one or more spacer ribs comprise one or more protuberances that extend into a space between adjacent coil turns of the induction coil, wherein grooves are formed between adjacent ones of the protuberances; and wherein the grooves are configured to receive therein at least portions of the induction coil.

20. The airflow diverter according to any one of claim 16, further comprising one or more turbulator features on the outer surface of the diverter body that are configured to induce turbulence in the airflow stream that flows through the outer region of the central coil cavity, wherein the one or more turbulator features comprise at least one of a helical ridge that wraps around the diverter body, a helical depression that wraps around the diverter body, a roughened surface, or a plurality of protuberances or tabs.
